(19) United States
(12) Patent Application Publication
(10) Pub. No.: US 2025/0078764 A1
(43) Pub. Date: Mar. 6, 2025

(54) DRIVING CIRCUIT, DISPLAY PANEL, DISPLAY SUBSTRATE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Yao HUANG, Beijing (CN); Tingliang LIU, Beijing (CN); Ming HU, Beijing (CN); Xiangdan DONG, Beijing (CN); Benlian WANG, Beijing (CN)

(21) Appl. No.: 18/553,445

(22) PCT Filed: Oct. 31, 2022
(86) PCT No.: PCT/CN2022/128669

§ 371 Date: Sep. 29, 2023

(51) Int. Cl. G09G 3/3266; G09G 3/3225; G11C 19/28

(52) U.S. Cl. CPC G09G 3/3266; G09G 3/3225; G09G 2300/0426; G09G 2300/0842; G09G 2300/0861; G09G 2310/0286; G09G 2310/08; G11C 19/287

(57) ABSTRACT

A driving circuit includes a first node control circuit, a second node control circuit and a first output circuit; the second node control circuit is configured to control to connect the first node and the second node under the control of a low voltage signal provided by the first low voltage input terminal; the first node control circuit is configured to control to connect the first node and the second low voltage input terminal under the control of a first clock signal provided by the first clock signal line; the first output circuit is configured to control to connect the driving signal output terminal and the third low voltage input terminal under the control of a potential of the pull-down node; at least two of the first low voltage input terminal, the second low voltage input terminal and the third low voltage input terminal are different from each other.

### TECHNICAL FIELD

The present disclosure relates to the field of display technology, in particular to a driving circuit, a display panel, a display substrate and a display device.

### BACKGROUND

Active-matrix organic light-emitting diode (AMOLED) display devices are widely used in various products due to their advantages of flexibility, high contrast ratio, and low power consumption.

In the related art, an AMOLED display device generally includes: an AMOLED display panel and a gate driving circuit. An AMOLED display panel includes a plurality of rows of pixels. The gate driving circuit includes a plurality of cascaded shift register units. Each shift register unit is coupled to a row of pixels, and is used for transmitting a gate driving signal to the row of pixels to driving the row of pixels to emit light. The plurality of cascaded shift register units can realize progressive scanning driving of a plurality of rows of pixels, so that the AMOLED display panel displays images.

However, the shift register units in the related art use the same voltage input terminal, and the potential of each node cannot be flexibly set.

### SUMMARY

In a first aspect, the present disclosure provides in some embodiments a driving circuit, comprising a first node control circuit, a second node control circuit and a first output circuit; the second node control circuit is electrically connected to a first low voltage input terminal, a first node and a second node respectively, and is configured to control to connect the first node and the second node under the control of a low voltage signal provided by the first low voltage input terminal; the first node control circuit is electrically connected to a second low voltage input terminal, a first clock signal line and the first node respectively, and is configured to control to connect the first node and the second low voltage input terminal under the control of a first clock signal provided by the first clock signal line; the first output circuit is electrically connected to a pull-down node, a driving signal output terminal and a third low voltage input terminal respectively, and is configured to control to connect the driving signal output terminal and the third low voltage input terminal under the control of a potential of the pull-down node; at least two of the first low voltage input terminal, the second low voltage input terminal and the third low voltage input terminal are different from each other.

Optionally, the driving circuit further includes a second output circuit and a fourth node control circuit; the second output circuit is respectively electrically connected to a pull-up node, a first high voltage input terminal and the driving signal output terminal, and is configured to control to connect the first high voltage input terminal and the driving signal output terminal under the control of a potential of the pull-up node; the fourth node control circuit is electrically connected to the first node, a fourth node and a fourth high voltage input terminal, and is configured to control to connect the fourth node and the fourth high voltage input terminal under the control of a potential of the first node; the first high voltage input terminal is different from the fourth high voltage input terminal.

Optionally, the driving circuit further includes a third node reset circuit; the third node reset circuit is respectively electrically connected to a reset line, a third high voltage input terminal and a third node, and is configured to control to connect the third high voltage input terminal and the third node under the control of a reset signal provided by the reset line; the third high voltage input terminal is different from at least one of the first high voltage input terminal or the fourth high voltage input terminal.

Optionally, the driving circuit further includes a pull-up node control circuit; the pull-up node control circuit is electrically connected to the third node, a second high voltage input terminal and the pull-up node, and is configured to control to connect the second high voltage input terminal and the pull-up node under the control of a potential of the third node; the second high voltage input terminal is different from at least one of the first high voltage input terminal or the fourth high voltage input terminal.

Optionally, the driving circuit further includes a pull-up node control circuit; the pull-up node control circuit is electrically connected to the third node, the second high voltage input terminal and the pull-up node, and is configured to control to connect the second high voltage input terminal and the pull-up node under the control of the potential of the third node; the second high voltage input terminal is different from the third high voltage input terminal.

Optionally, the driving circuit further includes a pull-down node control circuit; the pull-down node control circuit is electrically connected to a fourth low voltage input terminal, a third node, and the pull-down node, and is configured to control to connect the third node and the pull-down node under the control of a low voltage signal provided by the fourth low voltage input terminal; the fourth low voltage input terminal is different from at least one of the first low voltage input terminal, the second low voltage input terminal, or the third low voltage input terminal.

Optionally, the driving circuit further includes a fifth node control circuit and a pull-up node control circuit; the fifth node control circuit is electrically connected to the second node, a fifth node, and a second clock signal line, and is configured to connect the second clock signal line and the fifth node under the control of the potential of the second node, and control a potential of the fifth node according to the potential of the second node; the pull-up node control circuit is also electrically connected to the fifth node, the second clock signal line and the pull-up node, and is configured to control to connect the fifth node and the pull-up node under the control of a second clock signal provided by the second clock signal line and maintain the potential of the pull-up node under the control of the second clock signal provided by the second clock signal line.

Optionally, the driving circuit further includes a third node control circuit; the third node control circuit is electrically connected to a start voltage terminal, the first clock signal line and the third node, and is configured to control to connect the start voltage terminal and the third node under the control of the first clock signal provided by the first clock signal line; the first node control circuit is also electrically connected to the third node, the first node, and the first clock signal line, and is configured to control to connect the first node and the first clock signal line under the control of the potential of the third node; the fourth node control circuit is also electrically connected to the pull-down node and the second clock signal line, and is configured to control to connect the fourth node and the second clock signal line under the control of the potential of the pull-down node and control the potential of the fourth node according to the potential of the pull-down node.

Optionally, the first node control circuit comprises a first transistor, and the second node control circuit comprises a second transistor; a control electrode of the first transistor is electrically connected to the first clock signal line, a first electrode of the first transistor is electrically connected to the second low voltage input terminal, and a second electrode of the first transistor is electrically connected to the first node; a control electrode of the second transistor is electrically connected to the first low voltage input terminal, a first electrode of the second transistor is electrically connected to the first node, and a second electrode of the second transistor is electrically connected to the second node; the first output circuit includes an output reset transistor; a control electrode of the output reset transistor is electrically connected to the pull-down node, a first electrode of the output reset transistor is electrically connected to the driving signal output terminal, and a second electrode of the output reset transistor is electrically connected to the third low voltage input terminal.

Optionally, the second output circuit comprises an output transistor, and the pull-up node control circuit comprises a third transistor and a first capacitor; a control electrode of the output transistor is electrically connected to the pull-up node, a first electrode of the output transistor is electrically connected to the first high voltage input terminal, and a second electrode of the output transistor is electrically connected to the driving signal output terminal; a control electrode of the third transistor is electrically connected to the third node, a first electrode of the third transistor is electrically connected to the second high voltage input terminal, and a second electrode of the third transistor is electrically connected to the pull-up node; a first electrode plate of the first capacitor is electrically connected to the pull-up node, and a second electrode plate of the first capacitor is electrically connected to the first high voltage input terminal.

Optionally, the third node reset circuit comprises a fourth transistor; a control electrode of the fourth transistor is electrically connected to the reset line, a first electrode of the fourth transistor is electrically connected to the third high voltage input terminal, and a second electrode of the fourth transistor is electrically connected to the third node.

Optionally, the fourth node control circuit comprises a fifth transistor; a control electrode of the fifth transistor is electrically connected to the first node, a first electrode of the fifth transistor is electrically connected to the fourth high voltage input terminal, and a second electrode of the fifth transistor is electrically connected to the fourth node.

Optionally, the pull-down node control circuit comprises a sixth transistor; a control electrode of the sixth transistor is electrically connected to the fourth low voltage input terminal, a first electrode of the sixth transistor is electrically connected to the third node, and a second electrode of the sixth transistor is electrically connected to the pull-down node.

Optionally, the fifth node control circuit comprises a seventh transistor and a second capacitor; the pull-up node control circuit further comprises an eighth transistor; a control electrode of the seventh transistor is electrically connected to the second node, a first electrode of the seventh transistor is electrically connected to the second clock signal line, and a second electrode of the seventh transistor is electrically connected to a fifth node; a first electrode plate of the second capacitor is electrically connected to the second node, and a second electrode plate of the second capacitor is electrically connected to the fifth node; a control electrode of the eighth transistor is electrically connected to the second clock signal line, a first electrode of the eighth transistor is electrically connected to the fifth node, and a second electrode of the eighth transistor is electrically connected to the pull-up node.

Optionally, the first node control circuit further comprises a ninth transistor; a control electrode of the ninth transistor is electrically connected to the third node, a first electrode of the ninth transistor is electrically connected to the first clock signal line, and a second electrode of the ninth transistor is electrically connected to the first node; the fourth node control circuit further includes a tenth transistor and a third capacitor; a control electrode of the tenth transistor is electrically connected to the pull-down node, a first electrode of the tenth transistor is electrically connected to the second clock signal line, and a second electrode of the tenth transistor is electrically connected to the fourth node; a first electrode plate of the third capacitor is electrically connected to the pull-down node, and a second electrode plate of the third capacitor is electrically connected to the fourth node; the third node control circuit includes an eleventh transistor; a control electrode of the eleventh transistor is electrically connected to the first clock signal line, a first electrode of the eleventh transistor is electrically connected to the start voltage terminal, and a second electrode of the eleventh transistor is electrically connected to the third node.

In a second aspect, an embodiment of the present disclosure provides a driving circuit, including a first transistor, a second transistor, an output reset transistor and a sixth transistor; a control electrode of the first transistor is electrically connected to a first clock signal line, a first electrode of the first transistor is electrically connected to a second low voltage input terminal, and a second electrode of the first transistor is electrically connected to a first node; a control electrode of the second transistor is electrically connected to a first low voltage input terminal, a first electrode of the second transistor is electrically connected to the first node, and a second electrode of the second transistor is electrically connected to a second node; the first output circuit includes the output reset transistor, a control electrode of the output reset transistor is electrically connected to a pull-down node, a first electrode of the output reset transistor is electrically connected to a driving signal output terminal, and a second electrode of the output reset transistor is electrically connected to a third low voltage input terminal; a control electrode of the sixth transistor is electrically connected to a fourth low voltage input terminal, a first electrode of the sixth transistor is electrically connected to a third node, and a second electrode of the sixth transistor is electrically connected to the pull-down node; the first low voltage input terminal, the second low voltage input terminal, the third low voltage input terminal and the fourth low voltage input terminal are not completely the same.

In a third aspect, an embodiment of the present disclosure provides a driving circuit, comprising an output transistor, a third transistor, a fourth transistor and a fifth transistor; a control electrode of the output transistor is electrically connected to a pull-up node, a first electrode of the output transistor is electrically connected to a first high voltage input terminal, and a second electrode of the output transistor is electrically connected to a driving signal output terminal; a control electrode of the third transistor is electrically connected to a third node, a first electrode of the third transistor is electrically connected to a second high voltage input terminal, and a second electrode of the third transistor is electrically connected to the pull-up node; a control electrode of the fourth transistor is electrically connected to a reset line, a first electrode of the fourth transistor is electrically connected to a third high voltage input terminal, and a second electrode of the fourth transistor is electrically connected to a third node; a control electrode of the fifth transistor is electrically connected to a first node, a first electrode of the fifth transistor is electrically connected to a fourth high voltage input terminal, and a second electrode of the fifth transistor is electrically connected to a fourth node; the first high voltage input terminal, the second high voltage input terminal, the third high voltage input terminal and the fourth high voltage input terminal are not completely the same.

In a fourth aspect, an embodiment of the present disclosure provides a display panel, including the driving circuit; the display panel further comprises a display driving chip; the first low voltage input terminal is electrically connected to a first low voltage line, the second low voltage input terminal is electrically connected to a second low voltage line, the third low voltage input terminal is electrically connected to a third low voltage line, and the first low voltage line, the second low voltage line, and the third low voltage line are electrically connected to different pins of the display driving chip, and the display driving chip is configured to provide a first low voltage signal for the first low voltage line, provide a second low voltage signal for the second low voltage line, and provide a third low voltage signal for the third low voltage line; or, the first low voltage input terminal is electrically connected to the first low voltage line, the second low voltage input terminal and the third low voltage input terminal are both electrically connected to the second low voltage line, and the first low voltage line and the second low voltage line are respectively electrically connected to different pins of the display driving chip, the display driving chip is configured to provide the first low voltage signal for the first low voltage line, and provide the second low voltage signal for the second low voltage line; or, both the first low voltage input terminal and the second low voltage input terminal are electrically connected to the first low voltage line, the third low voltage input terminal is electrically connected to the second low voltage line, and the first low voltage line and the second low voltage line are respectively electrically connected to different pins of the display driving chip, the display driving chip is configured to provide the first low voltage signal for the first low voltage line, and provide the second low voltage signal for the second low voltage line; or, both the first low voltage input terminal and the third low voltage input terminal are electrically connected to the first low voltage line, the second low voltage input terminal is electrically connected to the second low voltage line, and the first low voltage line and the second low voltage line are respectively electrically connected to different pins of the display driving chip, and the display driving chip is configured to provide the first low voltage signal for the first low voltage line, and provide the second low voltage signal for the second low voltage line.

In a sixth aspect, an embodiment of the present disclosure provides a display panel, including the driving circuit; the display panel further comprises a display driving chip; the first high voltage input terminal is electrically connected to a first high voltage line, and the second high voltage input terminal is electrically connected to a second high voltage line; the first high voltage line and the second high voltage line are respectively electrically connected to different pins of the display driving chip, the display driving chip is configured to provide a first high voltage signal for the first high voltage line, and the display driving chip is configured to provide a second high voltage signal for the second high voltage line.

In a seventh aspect, an embodiment of the present disclosure provides a display substrate, including a base substrate and the driving circuit arranged on the base substrate.

Optionally, the driving circuit comprises a first low voltage line, a second low voltage line, a first high voltage line, a second high voltage line, a first node control circuit, a second node control circuit, a first output circuit, a second output circuit, a pull-up node control circuit, a fourth node control circuit, a pull-down node control circuit, a fifth node control circuit and a third node control circuit; the second low voltage line is arranged on a side of the driving circuit away from a display area, and the first low voltage line is arranged on a side of the driving circuit close to the display area; the first high voltage line and the second high voltage line are arranged between a first circuit part included in the driving circuit and a second circuit part included in the driving circuit; the first circuit part includes the first node control circuit, the second node control circuit, the pull-up node control circuit, the fourth node control circuit, the pull-down node control circuit, the fifth node control circuit and the third node control circuit, the second circuit part includes the first output circuit and the second output circuit; the first circuit part is arranged between the second low voltage line and the second high voltage line, and the second circuit part is arranged between the first high voltage line and the first low voltage line.

Optionally, the driving circuit further includes a third node reset circuit, and the first circuit part includes the third node reset circuit.

In an eighth aspect, an embodiment of the present disclosure provides a display device comprising the driving circuit.

### BRIEF DESCRIPTION OF THE DRAWINGS

FIG. 1 is a structural diagram of a driving circuit according to an embodiment of the present disclosure;

FIG. 2 is a structural diagram of a driving circuit according to at least one embodiment of the present disclosure;

FIG. 3 is a structural diagram of a driving circuit according to at least one embodiment of the present disclosure;

FIG. 4 is a structural diagram of a driving circuit according to at least one embodiment of the present disclosure;

FIG. 5 is a structural diagram of a driving circuit according to at least one embodiment of the present disclosure;

FIG. 6 is a structural diagram of a driving circuit according to at least one embodiment of the present disclosure;

FIG. 7 is a circuit diagram of a driving circuit according to at least one embodiment of the present disclosure;

FIG. 8A is a circuit diagram of a driving circuit according to at least one embodiment of the present disclosure;

FIG. 8B is a working timing diagram of the driving circuit shown in FIG. 8A of at least one embodiment of the present disclosure;

FIG. 9 is a circuit diagram of a driving circuit according to at least one embodiment of the present disclosure;

FIG. 10 is a circuit diagram of a driving circuit according to at least one embodiment of the present disclosure;

FIG. 11 is a circuit diagram of a driving circuit according to at least one embodiment of the present disclosure;

FIG. 12 is a circuit diagram of a driving circuit according to at least one embodiment of the present disclosure;

FIG. 13 is a circuit diagram of a driving circuit according to at least one embodiment of the present disclosure;

FIG. 14 is a circuit diagram of a driving circuit according to at least one embodiment of the present disclosure;

FIG. 15 is a circuit diagram of a driving circuit according to at least one embodiment of the present disclosure;

FIG. 16 is a circuit diagram of a driving circuit according to at least one embodiment of the present disclosure;

FIG. 17 is a circuit diagram of a driving circuit according to at least one embodiment of the present disclosure;

FIG. 18 is a circuit diagram of a driving circuit according to at least one embodiment of the present disclosure;

FIG. 19A is a circuit diagram of a driving circuit according to at least one embodiment of the present disclosure;

FIG. 19B is a structural diagram of a display panel according to at least one embodiment of the present disclosure;

FIG. 20 is a circuit diagram of a related pixel circuit;

FIG. 21 is a layout diagram of the driving circuit shown in FIG. 15 of at least one embodiment of the present disclosure;

FIG. 22 is a layout diagram of the active layer in FIG. 21;

FIG. 23 is a layout diagram of the first gate metal layer in FIG. 21;

FIG. 24 is a layout diagram of the second gate metal layer in FIG. 21;

FIG. 25 is a layout diagram of the source-drain metal layer in FIG. 21;

FIG. 26 is a layout diagram of the driving circuit shown in FIG. 19 of at least one embodiment of the present disclosure;

FIG. 27 is a layout diagram of the active layer in FIG. 26;

FIG. 28 is a layout diagram of the first gate metal layer in FIG. 26;

FIG. 29 is a layout diagram of the second gate metal layer in FIG. 26;

FIG. 30 is a layout diagram of the source-drain metal layer in FIG. 26;

FIG. 31 is a structural diagram of a display panel according to at least one embodiment of the present disclosure;

FIG. 32 is a structural diagram of a display panel according to at least one embodiment of the present disclosure;

FIG. 33 is a structural diagram of a display panel according to at least one embodiment of the present disclosure;

FIG. 34 is a structural diagram of a display panel according to at least one embodiment of the present disclosure;

FIG. 35 is a structural diagram of a display panel according to at least one embodiment of the present disclosure.

### DETAILED DESCRIPTION

The following will clearly and completely describe the technical solutions in the embodiments of the present disclosure with reference to the accompanying drawings. Obviously, the described embodiments are only some of the embodiments of the present disclosure, not all of them. Based on the embodiments in the present disclosure, all other embodiments obtained by those ordinary skill in the art without making creative work belong to the protection scope of the present disclosure.

The transistors used in all the embodiments of the present disclosure may be thin film transistors or field effect transistors or other devices with the same characteristics. In the embodiments of the present disclosure, in order to distinguish the two electrodes of the transistor except the control electrode, one electrode is called the first electrode, and the other electrode is called the second electrode.

In actual operation, when the transistor is a thin film transistor or a field effect transistor, the control electrode may be a gate electrode, the first electrode may be a drain electrode, and the second electrode may be a source electrode; or, the control electrode may be a gate electrode, the first electrode may be a source electrode, and the second electrode may be a drain electrode.

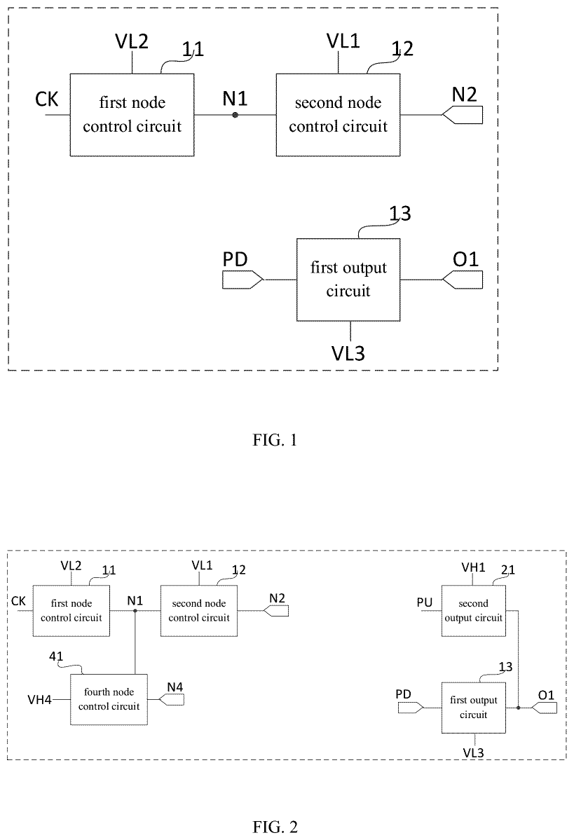

As shown in FIG. 1, the driving circuit described in the embodiment of the present disclosure includes a first node control circuit 11, a second node control circuit 12 and a first output circuit 13;

The second node control circuit 12 is electrically connected to a first low voltage input terminal VL1, a first node N1 and a second node N2 respectively, and is configured to control to connect the first node N1 and the second node N2 under the control of a low voltage signal provided by the first low voltage input terminal VL1;

The first node control circuit 11 is electrically connected to a second low voltage input terminal VL2, a first clock signal line CK and the first node N1 respectively, and is configured to control to connect the first node N1 and the second low voltage input terminal VL2 under the control of a first clock signal provided by the first clock signal line CK;

The first output circuit 13 is electrically connected to a pull-down node PD, a driving signal output terminal O1 and a third low voltage input terminal VL3 respectively, and is configured to control to connect the driving signal output terminal O1 and the third low voltage input terminal VL3 under the control of a potential of the pull-down node PD;

At least two of the first low voltage input terminal VL1, the second low voltage input terminal VL2 and the third low voltage input terminal VL3 are different from each other.

In at least one embodiment of the present disclosure, the two low voltage input terminals being different may refer to: low voltage signals respectively provided by the two low voltage input terminals are different.

In the embodiment of the driving circuit shown in FIG. 1, the low voltage signal provided by the first low voltage input terminal VL1 may be different from the low voltage signal provided by the second low voltage input terminal VL2.

In at least one embodiment of the present disclosure, the voltage value of the low voltage signal may be a negative voltage.

For example, when the transistors included in the first node control circuit 11 and the transistors included in the second node control circuit 12 are p-type transistors, an absolute value of the low voltage signal provided by the second low voltage input terminal VL2 is greater than that of the low voltage signal provided by the first low voltage input terminal VL1, so that the potential of N1 and the potential of N2 are lower.

In at least one embodiment of the present disclosure, the first low voltage input terminal may provide a first low voltage signal, and the second low voltage input terminal may provide a second low voltage signal, but not limited thereto.

In at least one embodiment of the present disclosure, the first low voltage signal may be provided by the first low voltage line VGL, and the second low voltage signal may be provided by the second low voltage line VGL2.

In the embodiment of the driving circuit shown in FIG. 1, the first low voltage input terminal VL1 can provide a first low voltage signal, the second low voltage input terminal VL2 can provide a second low voltage signal, and the third low voltage input terminal VL3 can provide a first low voltage signal; or,

The first low voltage input terminal VL1 can provide a second low voltage signal, the second low voltage input terminal VL2 can provide a second low voltage signal, and the third low voltage input terminal VL3 can provide a first low voltage signal; or,

The first low voltage input terminal VL1 can provide a first low voltage signal, the second low voltage input terminal VL2 can provide a first low voltage signal, and the third low voltage input terminal VL3 can provide a second low voltage signal; or,

The first low voltage input terminal VL1 can provide a first low voltage signal, the second low voltage input terminal VL2 can provide a second low voltage signal, and the third low voltage input terminal VL3 can provide a second low voltage signal;

But not limited to this.

As shown in FIG. 2, on the basis of the embodiment of the driving circuit shown in FIG. 1, the driving circuit described in at least one embodiment of the present disclosure further includes a second output circuit 21 and a fourth node control circuit 41;

The second output circuit 21 is respectively electrically connected to the pull-up node PU, the first high voltage input terminal VH1 and the driving signal output terminal O1, and is configured to control to connect the first high voltage input terminal VH1 and the driving signal output terminal O1 under the control of the potential of the pull-up node PU;

The fourth node control circuit 41 is electrically connected to the first node N1, the fourth node N4 and the fourth high voltage input terminal VH4, and is configured to control to connect the fourth node N4 and the fourth high voltage input terminal VH4 under the control of the potential of the first node N1; the first high voltage input terminal VH1 is different from the fourth high voltage input terminal VH4.

In at least one embodiment of the present disclosure, the two high voltage input terminals being different may refer to: the high voltage signals provided by the two high voltage input terminals are different.

In at least one embodiment of the present disclosure, the first high voltage input terminal VH1 can provide a first high voltage signal, and the second high voltage input terminal VH2 can provide a second high voltage signal.

In at least one embodiment of the present disclosure, the first high voltage signal may be provided by the first high voltage line VGH, and the second high voltage signal may be provided by the second high voltage line VGH2.

In specific implementation, when the transistors included in the second output circuit 21 are p-type transistors, the voltage value of the high voltage signal provided by the first high voltage input terminal can be set to be smaller than that of the high voltage signal provided by the second high voltage input terminal, so that when the transistor included in the pull-up node control circuit 22 is turned on, the transistor included in the second output circuit 21 can be better turned off;

When the transistors included in the second output circuit 21 are n-type transistors, the voltage value of the high voltage signal provided by the first high voltage input terminal can be set to be greater than the voltage value of the high voltage signal provided by the second high voltage input terminal, so that when the transistor included in the pull-up node control circuit 22 is turned on, the transistor included in the second output circuit 21 can be better turned off;

But not limited to this.

In at least one embodiment of the present disclosure, the driving circuit further includes a third node reset circuit;

The third node reset circuit is respectively electrically connected to a reset line, a third high voltage input terminal and a third node, and is configured to control to connect the third high voltage input terminal and the third node under the control of a reset signal provided by the reset line;

The third high voltage input terminal is different from at least one of the first high voltage input terminal and the second high voltage input terminal.

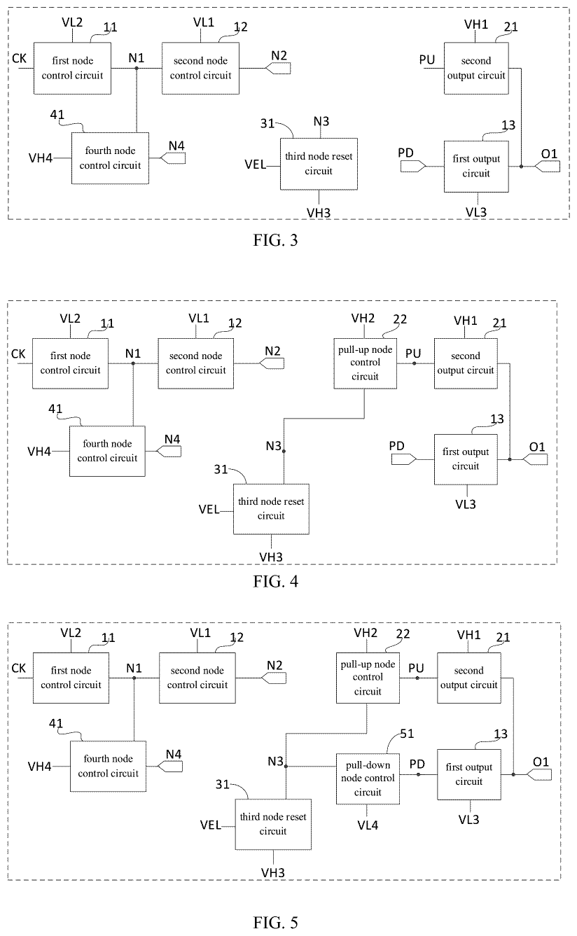

As shown in FIG. 3, on the basis of at least one embodiment of the driving circuit shown in FIG. 2, the driving circuit described in at least one embodiment of the present disclosure may further include a third node reset circuit 31;

The third node reset circuit 31 is electrically connected to the reset line VEL, the third high voltage input terminal VH3 and the third node N3 respectively, and is configured to control to connect the third high voltage input terminal VH3 and the third node N3 under the control of a reset signal provided by the reset line VEL.

In at least one embodiment shown in FIG. 3, the third high voltage input terminal VH3 can be configured to provide the second high voltage signal, or the third high voltage input terminal VH3 can be configured to provide the first high voltage signal, but not limited to.

In at least one embodiment of the present disclosure, the voltage value of the first low voltage signal may be greater than the voltage value of the second low voltage signal; or, the voltage value of the first low voltage signal may be smaller than the voltage value of the second low voltage signal;

The voltage value of the first high voltage signal may be greater than the voltage value of the second high voltage signal; or, the voltage value of the first high voltage signal may be smaller than the voltage value of the second high voltage signal.

The driving circuit described in at least one embodiment of the present disclosure further includes a pull-up node control circuit;

The pull-up node control circuit is electrically connected to the third node, the second high voltage input terminal and the pull-up node, and is configured to control to connect the second high voltage input terminal and the pull-up node under the control of the potential of the third node;

The second high voltage input terminal is different from at least one of the first high voltage input terminal and the fourth high voltage input terminal.

The driving circuit described in at least one embodiment of the present disclosure further includes a pull-up node control circuit;

The pull-up node control circuit is electrically connected to the third node, the second high voltage input terminal and the pull-up node, and is configured to control to connect the second high voltage input terminal and the pull-up node under the control of the potential of the third node;

The second high voltage input terminal is different from the third high voltage input terminal.

As shown in FIG. 4, on the basis of at least one embodiment of the driving circuit shown in FIG. 3, the driving circuit described in at least one embodiment of the present disclosure further includes a pull-up node control circuit 22;

The pull-up node control circuit 22 is electrically connected to the third node N3, the second high voltage input terminal VH2 and the pull-up node PU, and is configured to control to connect the second high voltage input terminal VH2 and the pull-up node PU under the control of the potential of the third node N3;

The second high voltage input terminal VH2 is different from at least one of the first high voltage input terminal VH1, the fourth high voltage input terminal VH4 and the third high voltage input terminal VH3.

In a specific implementation, the fourth high voltage input terminal VH4 may provide the first high voltage signal or the second high voltage signal, but not limited thereto.

In at least one embodiment of the present disclosure, the driving circuit further includes a pull-down node control circuit;

The pull-down node control circuit is electrically connected to a fourth low voltage input terminal, a third node, and the pull-down node, and is configured to control to connect the third node and the pull-down node under the control of the fourth low voltage signal provided by the fourth low voltage input terminal;

The fourth low voltage input terminal is different from at least one of the first low voltage input terminal, the second low voltage input terminal, and the third low voltage input terminal.

As shown in FIG. 5, on the basis of at least one embodiment of the driving circuit shown in FIG. 4, the driving circuit described in at least one embodiment of the present disclosure further includes a pull-down node control circuit 51;

The pull-down node control circuit 51 is electrically connected to the fourth low voltage input terminal VL4, the third node N3, and the pull-down node PD, respectively, is configured to control to connect the third node N3 and the pull-down node PD under the control of the fourth low voltage signal provided by the fourth low voltage input terminal VL4;

The fourth low voltage input terminal VL4 is different from at least one of the first low voltage input terminal VL1, the second low voltage input terminal VL2, and the third low voltage input terminal VL3.

In at least one embodiment of the present disclosure, the fourth low voltage input terminal VL4 may provide a first low voltage signal or a second low voltage signal, but not limited thereto.

In at least one embodiment of the present disclosure, the driving circuit further includes a fifth node control circuit and a pull-up node control circuit;

The fifth node control circuit is electrically connected to the second node, a fifth node, and a second clock signal line, and is configured to connect the second clock signal line and the fifth node under the control of the potential of the second node, and control a potential of the fifth node according to the potential of the second node;

The pull-up node control circuit is also electrically connected to a fifth node, a second clock signal line and the pull-up node, and is configured to control to connect the fifth node and the pull-up node under the control of the second clock signal provided by the second clock signal line and maintain the potential of the pull-up node under the control of the second clock signal provided by the second clock signal line.

In a specific implementation, the driving circuit further includes a fifth node control circuit, the fifth node control circuit is configured to control a potential of the fifth node, and the pull-up node control circuit is configured to control the potential of the pull-up node.

In at least one embodiment of the present disclosure, the driving circuit further includes a third node control circuit;

The third node control circuit is electrically connected to a start voltage terminal, the first clock signal line and the third node, and is configured to control to connect the star voltage terminal and the third node under the control of the first clock signal provided by the first clock signal line;

The first node control circuit is also electrically connected to the third node, the first node, and the first clock signal line, and is configured to control to connect the first node and the first clock signal line under the control of the potential of the third node;

The fourth node control circuit is also electrically connected to the pull-down node and the second clock signal line, and is configured to control to connect the fourth node and the second clock signal line under the control of the potential of the pull-down node and control the potential of the fourth node according to the potential of the pull-down node.

In specific implementation, the driving circuit further includes a third node control circuit, the third node control circuit controls the potential of the third node, the first node control circuit controls the potential of the first node, and the fourth node control circuit controls the potential of the fourth node.

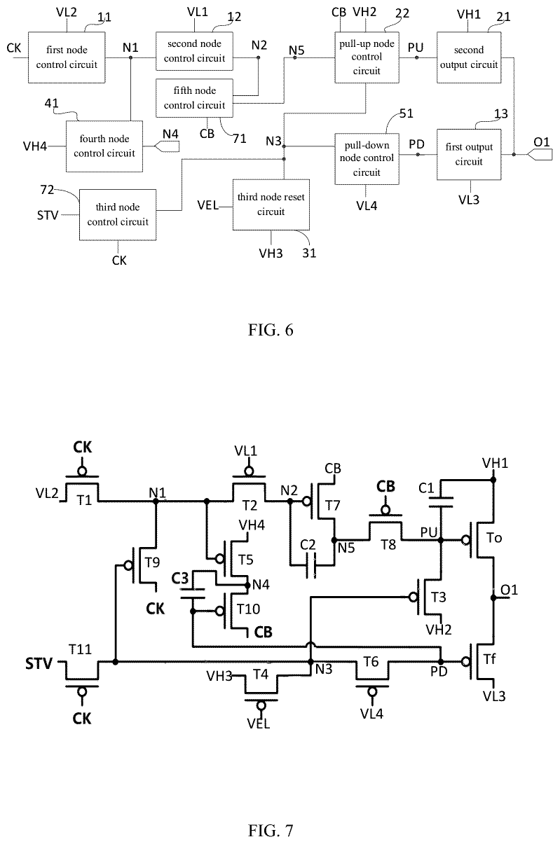

As shown in FIG. 6, on the basis of at least one embodiment of the driving circuit shown in FIG. 5, the driving circuit further includes a fifth node control circuit 71 and a third node control circuit 72;

The fifth node control circuit 71 is electrically connected to the second node N2, the fifth node N5 and the second clock signal line CB, and is configured to control to connect the second clock signal line CB and the fifth node N5 under the control of the potential of the second node N2, and controls the potential of the fifth node N5 according to the potential of the second node N2;

The pull-up node control circuit 22 is also electrically connected to the fifth node N5, the second clock signal line CB, and the pull-up node PU, is configured to control to connect the fifth node N5 and the pull-up node PU under the control of the second clock signal provided by the second clock signal line CB, and maintain the potential of the pull-up node PU;

The third node control circuit 72 is electrically connected to the start voltage terminal STV, the first clock signal line CK and the third node N3 respectively, and is configured to control to connect the start voltage terminal STV and the third node N3 under the control of the first clock signal provided by the first clock signal line CK;

The first node control circuit 11 is also electrically connected to the third node N3, the first node N1 and the first clock signal line CK, is configured to control to connect the first node N1 and the first clock signal line CK under the control of the potential of the third node N3;

The fourth node control circuit 41 is also electrically connected to the pull-down node PD and the second clock signal line CB, is configured to control to connect the fourth node N4 and the second clock signal line CB under the control of the potential of the pull-down node PD, and control the potential of the fourth node N4 according to the potential of the pull-down node PD.

Optionally, the first node control circuit includes a first transistor, and the second node control circuit includes a second transistor;

A control electrode of the first transistor is electrically connected to the first clock signal line, a first electrode of the first transistor is electrically connected to the second low voltage input terminal, and a second electrode of the first transistor is electrically connected to the first node;

A control electrode of the second transistor is electrically connected to the first low voltage input terminal, a first electrode of the second transistor is electrically connected to the first node, and a second electrode of the second transistor is electrically connected to the second node;

The first output circuit includes an output reset transistor;

A control electrode of the output reset transistor is electrically connected to the pull-down node, a first electrode of the output reset transistor is electrically connected to the driving signal output terminal, and a second electrode of the output reset transistor is electrically connected to the third low voltage input terminal.

Optionally, the second output circuit includes an output transistor, and the pull-up node control circuit includes a third transistor and a first capacitor;

A control electrode of the output transistor is electrically connected to the pull-up node, a first electrode of the output transistor is electrically connected to the first high voltage input terminal, and a second electrode of the output transistor is electrically connected to the driving signal output terminal;

A control electrode of the third transistor is electrically connected to the third node, a first electrode of the third transistor is electrically connected to the second high voltage input terminal, and a second electrode of the third transistor is electrically connected to the pull-up node;

A first electrode plate of the first capacitor is electrically connected to the pull-up node, and a second electrode plate of the first capacitor is electrically connected to the first high voltage input terminal.

Optionally, the third node reset circuit includes a fourth transistor;

A control electrode of the fourth transistor is electrically connected to the reset line, a first electrode of the fourth transistor is electrically connected to the third high voltage input terminal, and a second electrode of the fourth transistor is electrically connected to the third node.

Optionally, the fourth node control circuit includes a fifth transistor;

A control electrode of the fifth transistor is electrically connected to the first node, a first electrode of the fifth transistor is electrically connected to the fourth high voltage input terminal, and a second electrode of the fifth transistor is electrically connected to the fourth node.

Optionally, the pull-down node control circuit includes a sixth transistor;

A control electrode of the sixth transistor is electrically connected to the fourth low voltage input terminal, a first electrode of the sixth transistor is electrically connected to the third node, and a second electrode of the sixth transistor is electrically connected to the pull-down node.

Optionally, the fifth node control circuit includes a seventh transistor and a second capacitor; the pull-up node control circuit further includes an eighth transistor;

A control electrode of the seventh transistor is electrically connected to the second node, a first electrode of the seventh transistor is electrically connected to the second clock signal line, and a second electrode of the seventh transistor is electrically connected to a fifth node;

A first electrode plate of the second capacitor is electrically connected to the second node, and a second electrode plate of the second capacitor is electrically connected to the fifth node;

A control electrode of the eighth transistor is electrically connected to the second clock signal line, a first electrode of the eighth transistor is electrically connected to the fifth node, and a second electrode of the eighth transistor is electrically connected to the pull-up node.

Optionally, the first node control circuit further includes a ninth transistor;

A control electrode of the ninth transistor is electrically connected to the third node, a first electrode of the ninth transistor is electrically connected to the first clock signal line, and a second electrode of the ninth transistor is electrically connected to the first node;

The fourth node control circuit further includes a tenth transistor and a third capacitor;

A control electrode of the tenth transistor is electrically connected to the pull-down node, a first electrode of the tenth transistor is electrically connected to the second clock signal line, and a second electrode of the tenth transistor is electrically connected to the fourth node;

A first electrode plate of the third capacitor is electrically connected to the pull-down node, and a second electrode plate of the third capacitor is electrically connected to the fourth node;

The third node control circuit includes an eleventh transistor;

A control electrode of the eleventh transistor is electrically connected to the first clock signal line, a first electrode of the eleventh transistor is electrically connected to the start voltage terminal, and a second electrode of the eleventh transistor is electrically connected to the third node.

As shown in FIG. 7, on the basis of at least one embodiment of the driving circuit shown in FIG. 6, the first node control circuit includes a first transistor T1, and the second node control circuit includes a second transistor T2;

The gate electrode of the first transistor T1 is electrically connected to the first clock signal line CK, the source electrode of the first transistor T1 is electrically connected to the second low voltage input terminal VL2, and the drain electrode of the first transistor T1 is electrically connected to the first node N1;

The gate electrode of the second transistor T2 is electrically connected to the first low voltage input terminal VL1, the source electrode of the second transistor T2 is electrically connected to the first node N1, and the drain electrode of the second transistor T2 is electrically connected to the second node N2;

The first output circuit includes an output reset transistor Tf;

The gate electrode of the output reset transistor Tf is electrically connected to the pull-down node PD, the source electrode of the output reset transistor Tf is electrically connected to the driving signal output terminal O1, and the drain electrode of the output reset transistor Tf is connected to the third low voltage input terminal VL3;

The second output circuit includes an output transistor To, and the pull-up node control circuit includes a third transistor T3 and a first capacitor C1;

The gate electrode of the output transistor To is electrically connected to the pull-up node PU, the source electrode of the output transistor To is electrically connected to the first high voltage input terminal VH1, and the drain electrode of the output transistor To is connected to the driving signal output terminal 01;

The gate electrode of the third transistor T3 is electrically connected to the third node N3, the source electrode of the third transistor T3 is electrically connected to the second high voltage input terminal VH2, and the drain electrode of the third transistor T3 is electrically connected to the pull-up node PU;

The first electrode plate of the first capacitor C1 is electrically connected to the pull-up node PU, and the second electrode plate of the first capacitor C1 is electrically connected to the first high voltage input terminal VH1;

The third node reset circuit includes a fourth transistor T4;

The gate electrode of the fourth transistor T4 is electrically connected to the reset line VEL, the source electrode of the fourth transistor T4 is electrically connected to the third high voltage input terminal VH3, and the drain electrode of the fourth transistor T4 is electrically connected to the third Node N3;

The fourth node control circuit includes a fifth transistor T5;

The gate electrode of the fifth transistor T5 is electrically connected to the first node N1, the source electrode of the fifth transistor T5 is electrically connected to the fourth high voltage input terminal VH4, and the drain electrode of the fifth transistor T5 is electrically connected to the fourth node N4;

The pull-down node control circuit includes a sixth transistor T6;

The gate electrode of the sixth transistor T6 is electrically connected to the fourth low voltage input terminal VL4, the source electrode of the sixth transistor T6 is electrically connected to the third node N3, and the drain electrode of the sixth transistor T6 is electrically connected to the pull-down node PD;

The fifth node control circuit includes a seventh transistor T7 and a second capacitor C2; the pull-up node control circuit further includes an eighth transistor T8;

The gate electrode of the seventh transistor T7 is electrically connected to the second node N2, the source electrode of the seventh transistor T7 is electrically connected to the second clock signal line CB, and the drain electrode of the seventh transistor T7 is electrically connected to the fifth Node N5;

The first electrode plate of the second capacitor C2 is electrically connected to the second node N2, and the second electrode plate of the second capacitor C2 is electrically connected to the fifth node N5;

The gate electrode of the eighth transistor T8 is electrically connected to the second clock signal line CB, the source electrode of the eighth transistor T8 is electrically connected to the fifth node N5, and the drain electrode of the eighth transistor T8 is electrically connected to the pull-up node PU;

The first node control circuit further includes a ninth transistor T9;

The gate electrode of the ninth transistor T9 is electrically connected to the third node N3, the source electrode of the ninth transistor T9 is electrically connected to the first clock signal line CK, and the drain electrode of the ninth transistor T9 is electrically connected to the first node N1;

The fourth node control circuit further includes a tenth transistor T10 and a third capacitor C3;

The gate electrode of the tenth transistor T10 is electrically connected to the pull-down node PD, the source electrode of the tenth transistor T10 is electrically connected to the second clock signal line CB, and the drain electrode of the tenth transistor T10 is electrically connected to the fourth node N4;

The first electrode plate of the third capacitor C3 is electrically connected to the pull-down node PD, and the second electrode plate of the third capacitor C3 is electrically connected to the fourth node N4;

The third node control circuit includes an eleventh transistor T11;

The gate electrode of the eleventh transistor T11 is electrically connected to the first clock signal line CK, the source electrode of the eleventh transistor T11 is electrically connected to the start voltage terminal STV, and the drain electrode of the eleventh transistor T11 is electrically connected to the third node N3.

In at least one embodiment of the driving circuit shown in FIG. 7, all transistors are p-type transistors, but not limited thereto. In actual operation, the transistors in FIG. 7 may also be n-type transistors.

In at least one embodiment of the driving circuit shown in FIG. 7, the first low voltage input terminal VL1 can provide a first low voltage signal, the second low voltage input terminal VL2 can provide a second low voltage signal, and the third low voltage input terminal VL3 can provide the first low voltage signal, and the fourth low voltage input terminal VL4 can provide the first low voltage signal; or,

The first low voltage input terminal VL1 can provide the second low voltage signal, the second low voltage input terminal VL2 can provide the second low voltage signal, the third low voltage input terminal VL3 can provide the first low voltage signal, and the fourth low voltage input terminal VL4 can provide a second low voltage signal; or,

The first low voltage input terminal VL1 can provide the first low voltage signal, the second low voltage input terminal VL2 can provide the first low voltage signal, the third low voltage input terminal VL3 can provide the first low voltage signal, and the fourth low voltage input terminal VL4 can provide the second low voltage signal; or,

The first low voltage input terminal VL1 can provide the second low voltage signal, the second low voltage input terminal VL2 can provide the first low voltage signal, the third low voltage input terminal VL3 can provide the first low voltage signal, and the fourth low voltage input terminal VL4 can provide the first low voltage signal; or,

The first low voltage input terminal VL1 can provide the second low voltage signal, the second low voltage input terminal VL2 can provide the first low voltage signal, the third low voltage input terminal VL3 can provide the first low voltage signal, and the fourth low voltage input terminal VL4 can provide the second low voltage signal; or,

The first low voltage input terminal VL1 can provide the second low voltage signal, the second low voltage input terminal VL2 can provide the second low voltage signal, the third low voltage input terminal VL3 can provide the second low voltage signal, and the fourth low voltage input terminal VL4 can provide the first low voltage signal; or,

The first low voltage input terminal VL1 can provide the first low voltage signal, the second low voltage input terminal VL2 can provide the second low voltage signal, the third low voltage input terminal VL3 can provide the second low voltage signal, and the fourth low voltage input terminal VL4 can provide the first low voltage signal; or,

The first low voltage input terminal VL1 can provide the first low voltage signal, the second low voltage input terminal VL2 can provide the first low voltage signal, the third low voltage input terminal VL3 can provide the second low voltage signal, and the fourth low voltage input terminal VL4 can provide the first low voltage signal;

But not limited to this.

In at least one embodiment of the driving circuit shown in FIG. 7,

The first high voltage input terminal VH1 can provide the first high voltage signal, the second high voltage input terminal VH2 can provide the second high voltage signal, the third high voltage input terminal VH3 can provide the second high voltage signal, and the fourth high voltage input terminal VH4 can provide the first high voltage signal; or,

The first high voltage input terminal VH1 can provide the first high voltage signal, the second high voltage input terminal VH2 can provide the second high voltage signal, the third high voltage input terminal VH3 can provide the first high voltage signal, and the fourth high voltage input terminal VH4 can provide the first high voltage signal; or,

The first high voltage input terminal VH1 can provide the first high voltage signal, the second high voltage input terminal VH2 can provide the second high voltage signal, the third high voltage input terminal VH3 can provide the first high voltage signal, and the fourth high voltage input terminal VH4 can provide the second high voltage signal; or,

The first high voltage input terminal VH1 can provide the second high voltage signal, the second high voltage input terminal VH2 can provide the first high voltage signal, the third high voltage input terminal VH3 can provide the second high voltage signal, and the fourth high voltage input terminal VH4 can provide the first high voltage signal; or,

The first high voltage input terminal VH1 can provide the second high voltage signal, the second high voltage input terminal VH2 can provide the first high voltage signal, the third high voltage input terminal VH3 can provide the first high voltage signal, and the fourth high voltage input terminal VH4 can provide the first high voltage signal; or,

The first high voltage input terminal VH1 can provide the second high voltage signal, the second high voltage input terminal VH2 can provide the first high voltage signal, the third high voltage input terminal VH3 can provide the first high voltage signal, and the fourth high voltage input terminal VH4 can provide the second high voltage signal;

But not limited to this.

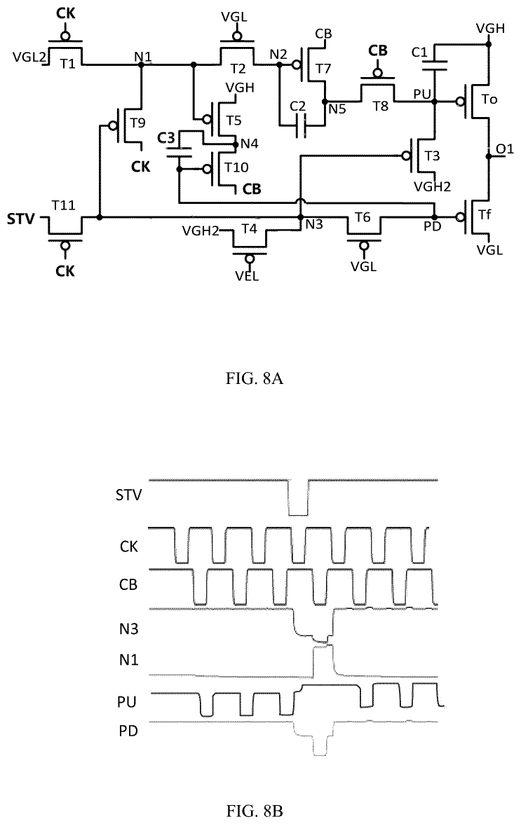

As shown in FIG. 8A, on the basis of at least one embodiment of the driving circuit shown in FIG. 7, the first low voltage input terminal VL1 provides a first low voltage signal, and the second low voltage input terminal VL2 provides a second low voltage signal, the third low voltage input terminal VL3 provides the first low voltage signal, and the fourth low voltage input terminal VL4 provides the first low voltage signal; the first low voltage signal is provided by the first low voltage line VGL, and the second low voltage signal is provided by the second low voltage line VGL2;

The first high voltage input terminal VH1 provides the first high voltage signal, the second high voltage input terminal VH2 provides the second high voltage signal, the third high voltage input terminal VH3 provides the second high voltage signal, and the fourth high voltage input terminal VH4 provides the first high voltage signal; the first high voltage signal is provided by the first high voltage line VGH, and the second high voltage signal is provided by the second high voltage line VGH2.

When at least one embodiment of the driving circuit shown in FIG. 8A of the present disclosure is in operation, the voltage value of the second low voltage signal provided by VGL2 may be smaller than the voltage value of the first low voltage signal provided by VGL, for example, when the voltage value of the first low voltage signal provided by VGL is −6V, the voltage value of the second low voltage signal provided by VGL2 can be −6.5V; since the p-type transistor has a threshold voltage loss when passing a low level, the voltage value thereof can be set as to be lower than that, so that when T1 and T2 are turned on, the potential of NI and the potential of N2 can be lower, so that the pull-up node PU is turned on faster, and the delay of the driving signal output by O1 is smaller.

In at least one embodiment of the present disclosure, the difference between the voltage value of the second low voltage signal and the voltage value of the first low voltage signal may be slightly greater than or equal to the threshold voltage of the p-type transistor.

At least one embodiment of the driving circuit shown in FIG. 8A of the present disclosure adopts two high voltage input terminals and two low voltage input terminals;

When performing low-frequency display, the voltage value of the high voltage signal provided by one high voltage input terminal and the absolute value of the voltage value of the low voltage signal provided by one low voltage input terminal can be appropriately reduced to reduce power consumption;

For example, when performing low-frequency display, the voltage value of the first high voltage signal and the voltage value of the first low voltage signal can be controlled to remain unchanged, but the voltage value of the second high voltage signal is reduced from 7V to 6V, and the voltage value of the second low voltage signal is adjusted from −7V to −6V to reduce power consumption.

At least one embodiment of the driving circuit shown in FIG. 8A of the present disclosure can increase the voltage value of the second high voltage signal from 7V to 10V, and adjust the voltage value of the second low voltage signal from −7V to −10V to enhance the on-off capability of To and Tf.

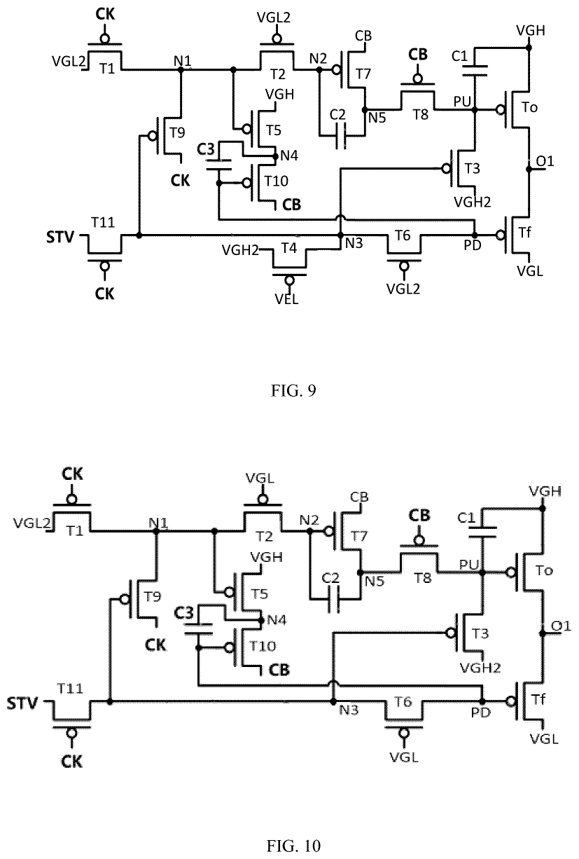

As shown in FIG. 9, on the basis of at least one embodiment of the driving circuit shown in FIG. 7, the first low voltage input terminal VL1 provides a second low voltage signal, and the second low voltage input terminal VL2 provides a second low voltage signal, the third low voltage input terminal VL3 provides a first low voltage signal, and the fourth low voltage input terminal VL4 provides a second low voltage signal; the first low voltage signal is provided by the first low voltage line VGL, and the second low voltage signal is provided by the second low voltage line VGL2;

The first high voltage input terminal VH1 provides the first high voltage signal, the second high voltage input terminal VH2 provides the second high voltage signal, the third high voltage input terminal VH3 provides the second high voltage signal, and the fourth high voltage input terminal VH4 provides the first high voltage signal; the first high voltage signal is provided by the first high voltage line VGH, and the second high voltage signal is provided by the second high voltage line VGH2.

In at least one embodiment of the present disclosure, the voltage value of VGH2 may be greater than the voltage value of VGH1 to compensate for current leakage effects caused by threshold voltage drift, but the present disclosure is not limited thereto.

In at least one embodiment of the driving circuit shown in FIG. 9, the gate electrode of T2 and the gate electrode of T6 are both electrically connected to the second low voltage line VGL2 that provides the second low voltage signal, which facilitates layout and improves space utilization rate.

The difference between at least one embodiment of the driving circuit shown in FIG. 10 of the present disclosure and at least one embodiment of the driving circuit shown in FIG. 8A of the present disclosure is that T4 is not provided.

The difference between at least one embodiment of the driving circuit shown in FIG. 11 of the present disclosure and at least one embodiment of the driving circuit shown in FIG. 9 of the present disclosure is that T4 is not provided.

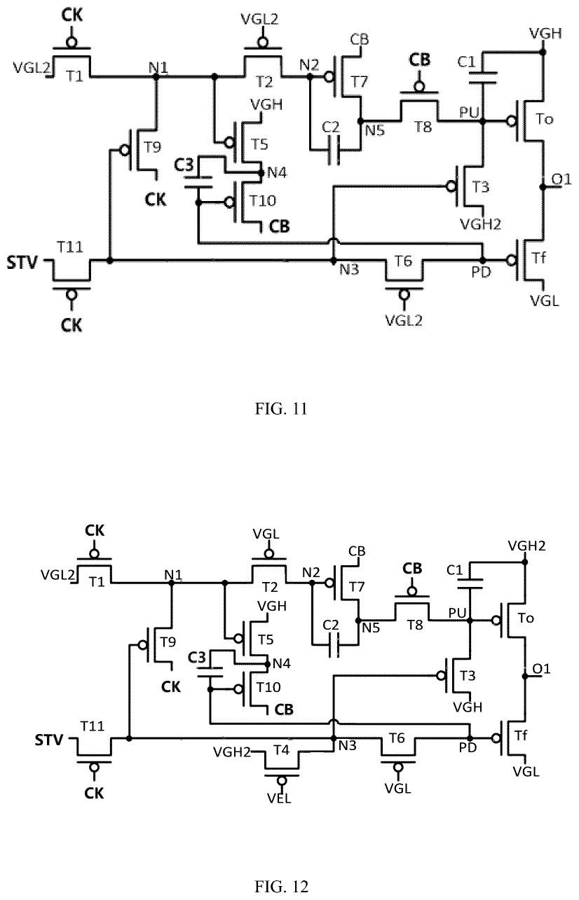

The difference between at least one embodiment of the driving circuit shown in FIG. 12 of the present disclosure and at least one embodiment of the driving circuit shown in FIG. 8A of the present disclosure is that the source electrode of To is electrically connected to the second high voltage line VGH2, and the source electrode of T3 is electrically connected to the first high voltage line VGH.

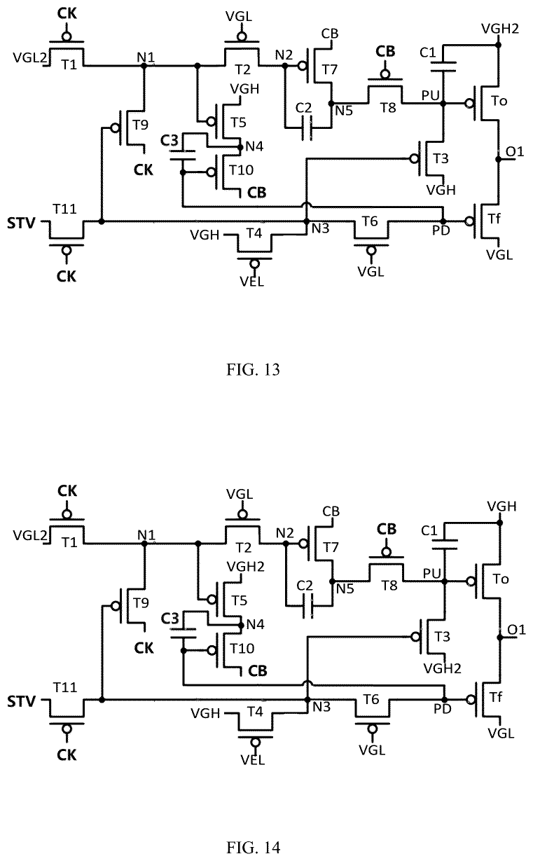

The difference between at least one embodiment of the driving circuit shown in FIG. 13 of the present disclosure and at least one embodiment of the driving circuit shown in FIG. 12 of the present disclosure is that the source electrode of T4 is electrically connected to the first high voltage line VGH.

The difference between at least one embodiment of the driving circuit shown in FIG. 14 of the present disclosure and at least one embodiment of the driving circuit shown in FIG. 13 of the present disclosure is that the source electrode of T5 is electrically connected to the second high voltage line VGH2.

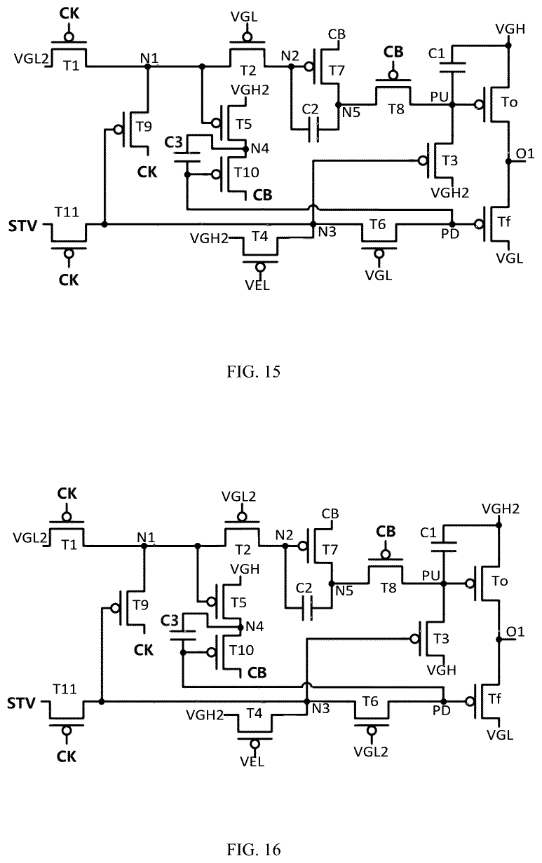

The difference between at least one embodiment of the driving circuit shown in FIG. 15 of the present disclosure and at least one embodiment of the driving circuit shown in FIG. 14 of the present disclosure is that the source electrode of T4 is electrically connected to the second high voltage line VGH2.

The difference between at least one embodiment of the driving circuit shown in FIG. 16 of the present disclosure and at least one embodiment of the driving circuit shown in FIG. 12 of the present disclosure is that the gate electrodes of T2 and T6 are both electrically connected to the second low voltage line VGL2.

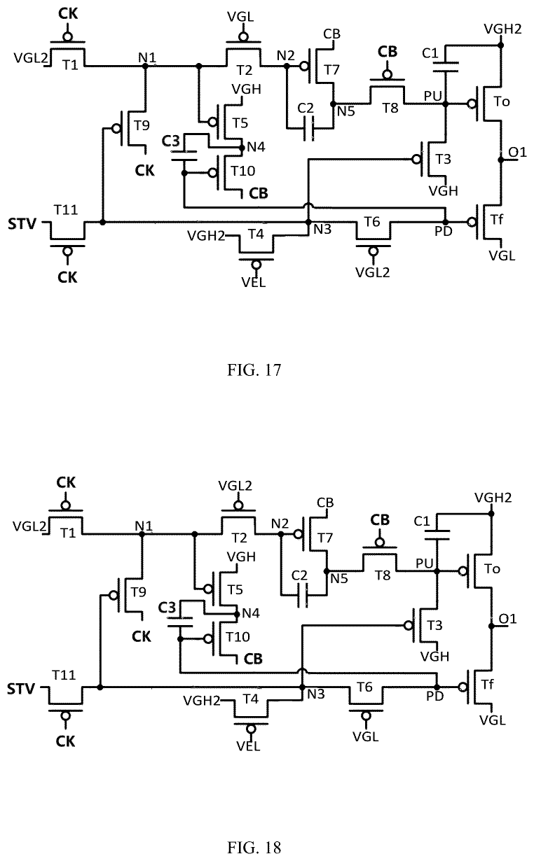

The difference between at least one embodiment of the driving circuit shown in FIG. 17 of the present disclosure and at least one embodiment of the driving circuit shown in FIG. 16 of the present disclosure is that the gate electrode of T2 is electrically connected to the first low voltage line VGL.

The difference between at least one embodiment of the driving circuit shown in FIG. 18 of the present disclosure and at least one embodiment of the driving circuit shown in FIG. 16 of the present disclosure is that the gate electrode of T6 is electrically connected to the first low voltage line VGL.

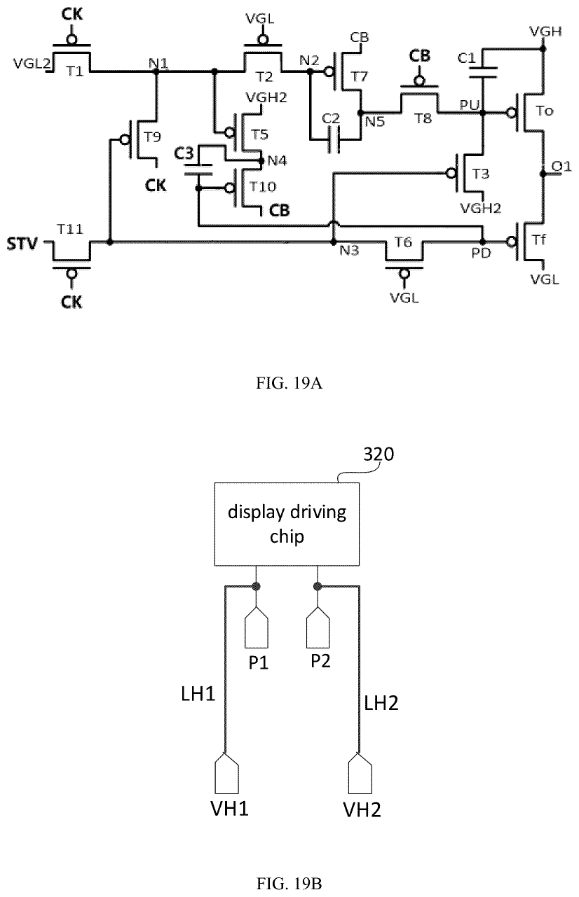

The difference between at least one embodiment of the driving circuit shown in FIG. 19A of the present disclosure and at least one embodiment of the driving circuit shown in FIG. 15 of the present disclosure is that T4 is not included.

The driving circuit described in at least one embodiment of the present disclosure includes a second output circuit and a pull-up node control circuit;

The second output circuit is electrically connected to the pull-up node, the first high voltage input terminal and the driving signal output terminal respectively, and is configured to control to connect the first high voltage input terminal and the driving signal output terminal under the control of the potential of the pull-up node;

The pull-up node control circuit is electrically connected to the third node, the second high voltage input terminal and the pull-up node, and is configured to control to connect the second high voltage input terminal and the pull-up node under the control of the potential of the third node;

The first high voltage input terminal is different from the second high voltage input terminal.

In at least one embodiment of the present disclosure, the driving circuit further includes a third node reset circuit;

The third node reset circuit is respectively electrically connected to the reset line, the third high voltage input terminal and the third node, and is configured to control to connect the third high voltage input terminal and the third node under the control of the reset signal provided by the reset line;

The third high voltage input terminal is different from at least one of the first high voltage input terminal and the second high voltage input terminal.

In at least one embodiment of the present disclosure, the driving circuit further includes a fourth node control circuit;

The fourth node control circuit is electrically connected to the first node, the fourth node, and the fourth high voltage input terminal, and is configured to control to connect the fourth node and the fourth high voltage input terminal under the control of the potential of the first node;

The fourth high voltage input terminal is different from at least one of the first high voltage input terminal and the second high voltage input terminal.

In at least one embodiment of the present disclosure, the driving circuit further includes a fourth node control circuit;

The fourth node control circuit is electrically connected to the first node, the fourth node, and the fourth high voltage input terminal, and is configured to control to connect the fourth node and the fourth high voltage input terminal under the control of the potential of the first node;

The fourth high voltage input terminal is different from the third high voltage input terminal.

An embodiment of the present disclosure also provides a display panel, including the above driving circuit; the display panel further includes a display driving chip;

The first high voltage input terminal is electrically connected to the first high voltage line, and the second high voltage input terminal is electrically connected to the second high voltage line; the first high voltage line and the second high voltage line are respectively electrically connected to different pins of the display driving chip, the display driving chip is configured to provide the first high voltage signal to the first high voltage line, and the display driving chip is configured to provide the second high voltage signal to the second high voltage line.

In the display panel described in the embodiment of the present disclosure, the first high voltage input terminal is electrically connected to the first high voltage line, the second high voltage input terminal is electrically connected to the second high voltage line, and the first high voltage line is electrically connected to the first pin of the display driving chip, the second high voltage line is electrically connected to the second pin of the display driving chip, and the display driving chip provides the first high voltage signal to the first high voltage line through the first pin, and the display driving chip provides a second high voltage signal to the second high voltage line through a second pin.

As shown in FIG. 19B, the display panel includes a display driving chip 320;

The first high voltage input terminal VH1 is electrically connected to the first high voltage line LH1, and the second high voltage input terminal VH2 is electrically connected to the second high voltage line LH2;

The first high voltage line LH1 is electrically connected to the first pin P1 of the display driving chip 320, and the second high voltage line LH2 is electrically connected to the second pin P2 of the display driving chip 320;

The display driving chip 320 is configured to provide the first high voltage signal to the first high voltage line LH1, and the display driving chip 320 is configured to provide the second high voltage signal to the second high voltage line LH2.

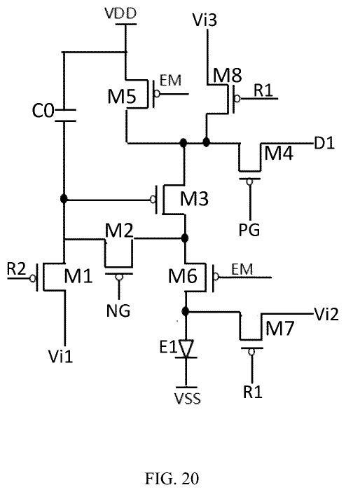

As shown in FIG. 20, the relevant pixel circuit includes a first display control transistor M1, a second display control transistor M2, a third display control transistor M3, a fourth display control transistor M4, a fifth display control transistor M5, a sixth display control transistor M6, a seventh display control transistor M7, an eighth display control transistor M8, a storage capacitor C0 and an organic light emitting diode E1;

In FIG. 20, the one labeled EM is the light emitting control line, the one labeled R1 is the first reset control line, the one labeled R2 is the second reset control line, the one labeled NG is the first scanning line, and the one labeled PG is the second scanning line, the one labeled Vi1 is the first initial voltage, the one labeled Vi2 is the second initial voltage, the one labeled Vi3 is the third initial voltage, the one labeled VDD is the high level terminal, and the one labeled VSS is the low level terminal.

The driving circuit described in at least one embodiment of the present disclosure can be configured to provide the first scanning signal for the first scanning line NG, provide the light emitting control signal for the light emitting control line EM, provide the first reset control signal for the first reset control line R1, and provide a second reset control signal for the second reset control line R2.

The driving circuit described in at least one embodiment of the present disclosure includes a first transistor, a second transistor, an output reset transistor, and a sixth transistor;

A control electrode of the first transistor is electrically connected to the first clock signal line, a first electrode of the first transistor is electrically connected to the second low voltage input terminal, and a second electrode of the first transistor is electrically connected to the first node;

A control electrode of the second transistor is electrically connected to the first low voltage input terminal, a first electrode of the second transistor is electrically connected to the first node, and a second electrode of the second transistor is electrically connected to the second node;

The first output circuit includes an output reset transistor, a control electrode of the output reset transistor is electrically connected to the pull-down node, a first electrode of the output reset transistor is electrically connected to the driving signal output terminal, and a second electrode of the output reset transistor is electrically connected to the third low voltage input terminal;

A control electrode of the sixth transistor is electrically connected to the fourth low voltage input terminal, a first electrode of the sixth transistor is electrically connected to the third node, and a second electrode of the sixth transistor is electrically connected to the pull-down node;

The first low voltage input terminal, the second low voltage input terminal, the third low voltage input terminal and the fourth low voltage input terminal are not completely the same.

In at least one embodiment of the present disclosure, the first low voltage input terminal VL1, the second low voltage input terminal VL2, the third low voltage input terminal VL3, and the fourth low voltage input terminal VL4 are not completely the same, as follows:
VL1 and VL2 are not the same; or,
VL1 and VL3 are not the same; or,
VL1 and VL4 are not the same; or,
VL2 and VL3 are not the same; or,
VL2 and VL4 are not the same; or,
VL3 and VL4 are not the same; or,
VL1, VL2 and VL3 are different from each other; or,
VL1, VL2 and VL4 are different from each other; or,
VL1, VL3, and VL4 are different from each other; or,
VL2, VL3 and VL4 are different from each other; or,
VL1, VL2, VL3 and VL4 are different from each other.

The driving circuit described in at least one embodiment of the present disclosure includes an output transistor, a third transistor, a fourth transistor, and a fifth transistor;

A control electrode of the output transistor is electrically connected to the pull-up node, a first electrode of the output transistor is electrically connected to the first high voltage input terminal, and a second electrode of the output transistor is electrically connected to the driving signal output terminal;

A control electrode of the third transistor is electrically connected to the third node, a first electrode of the third transistor is electrically connected to the second high voltage input terminal, and a second electrode of the third transistor is electrically connected to the pull-up node;

A control electrode of the fourth transistor is electrically connected to the reset line, a first electrode of the fourth transistor is electrically connected to the third high voltage input terminal, and a second electrode of the fourth transistor is electrically connected to the third node;

A control electrode of the fifth transistor is electrically connected to the first node, a first electrode of the fifth transistor is electrically connected to the fourth high voltage input terminal, and a second electrode of the fifth transistor is electrically connected to the fourth node;

The first high voltage input terminal, the second high voltage input terminal, the third high voltage input terminal and the fourth high voltage input terminal are not completely the same.

In at least one embodiment of the present disclosure, the first high voltage input terminal VH1, the second high voltage input terminal VH2, the third high voltage input terminal VH3 and the fourth high voltage input terminal VH4 are not completely the same, as follows:
VH1 and VH2 are not the same; or,
VH1 and VH3 are not the same; or,
VH1 and VH4 are not the same; or,
VH2 and VH3 are not the same; or,
VH2 and VH4 are not the same; or,
VH3 and VH4 are not the same; or,
VH1, VH2, and VH3 are different from each other; or,
VH1, VH2 and VH4 are different from each other; or,
VH1, VH3 and VH4 are different from each other; or,
VH2, VH3 and VH4 are different from each other; or,
VH1, VH2, VH3 and VH4 are different from each other.

The display substrate described in the embodiment of the present disclosure includes a base substrate and the driving circuit arranged on the base substrate.

Optionally, the driving circuit includes a first low voltage line, a second low voltage line, a first high voltage line, a second high voltage line, a first node control circuit, a second node control circuit, a first output circuit, a second output circuit, a pull-up node control circuit, a fourth node control circuit, a pull-down node control circuit, a fifth node control circuit and a third node control circuit;

The second low voltage line is arranged on a side of the driving circuit away from a display area, and the first low voltage line is arranged on a side of the driving circuit close to the display area;

The first high voltage line and the second high voltage line are arranged between a first circuit part included in the driving circuit and a second circuit part included in the driving circuit;

The first circuit part includes a first node control circuit, a second node control circuit, a pull-up node control circuit, a fourth node control circuit, a pull-down node control circuit, a fifth node control circuit and a third node control circuit, the second circuit part includes a first output circuit and a second output circuit;

The first circuit part is arranged between the second low voltage line and the second high voltage line, and the second circuit part is arranged between the first high voltage line and the first low voltage line, so as to driving electrodes of the transistors in the driving circuit are electrically connected to corresponding voltage lines.

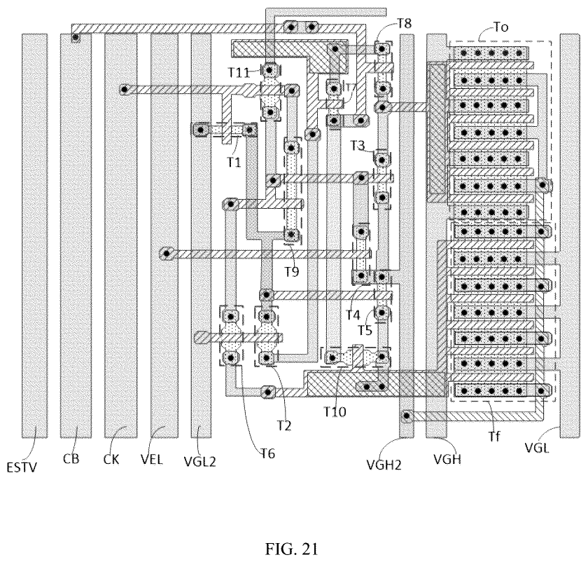

In at least one embodiment of the present disclosure, the driving circuit further includes a third node reset circuit, and the first circuit part includes the third node reset circuit. FIG. 21 is a layout diagram of the driving circuit shown in FIG. 15 of at least one embodiment of the present disclosure.

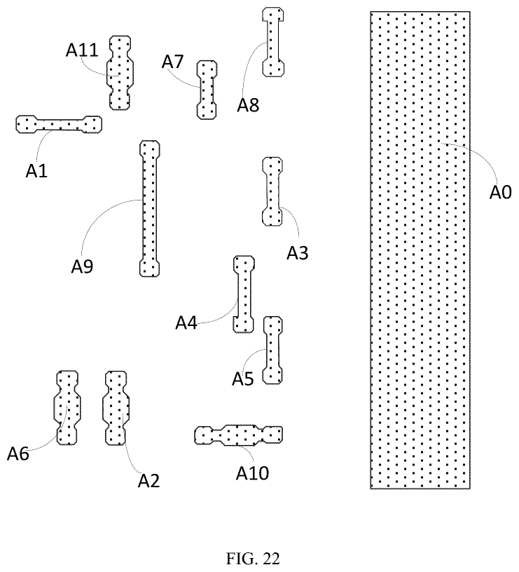

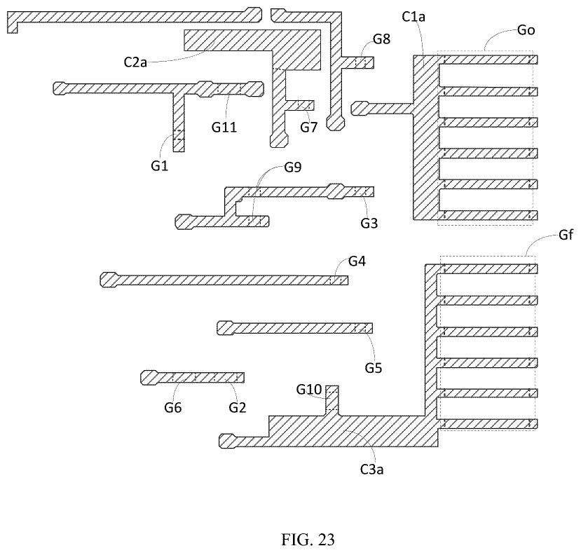

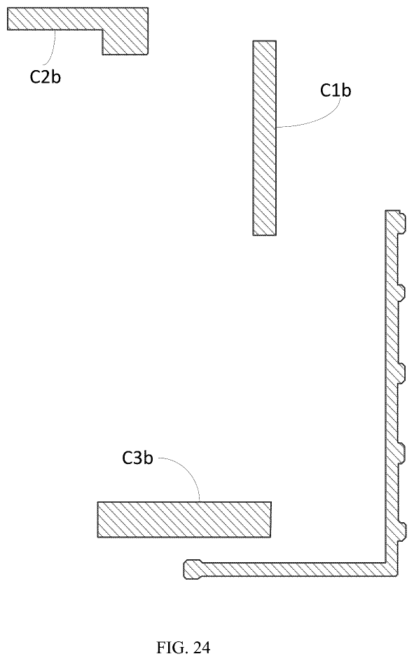

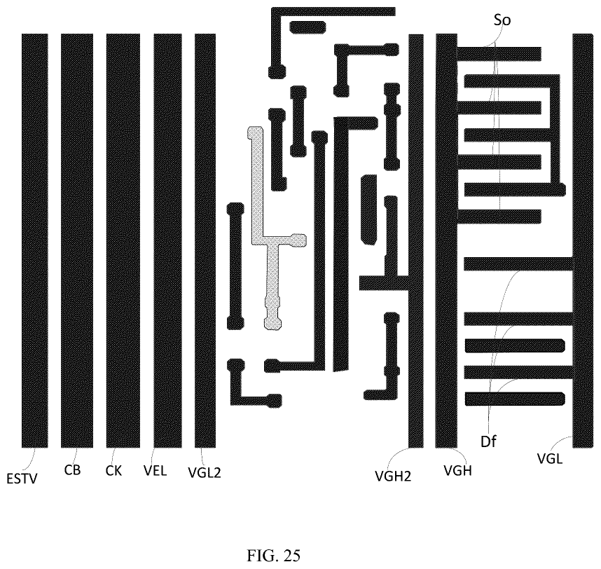

FIG. 22 is a layout diagram of the active layer in FIG. 21, FIG. 23 is a layout diagram of the first gate metal layer in FIG. 21, FIG. 24 is a layout diagram of the second gate metal layer in FIG. 21, FIG. 25 is a layout diagram of the source-drain metal layer in FIG. 21.

In FIG. 21 and FIG. 25, the one labeled ESTV is the start signal line, the one labeled CB is the second clock signal line, the one labeled CK is the first clock signal line, the one labeled VEL is the reset line, the one labeled VEL is the reset line, the one labeled VGL2 is the first low voltage line, the one labeled VGH2 is the second high voltage line, the one labeled VGH is the first high voltage line, and the one labeled VGL is the first low voltage line.

As shown in FIG. 21, the start signal line ESTV, the second clock signal line CB, the first clock signal line CK, the reset line VEL, the second low voltage line VGL2, the second high voltage line VGH2, the first high voltage line VGH and the first low voltage line VGL all extend along the vertical direction;

The start signal line ESTV, the second clock signal line CB, the first clock signal line CK, the reset line VEL and the second low voltage line VGL2 are arranged on the side of the driving circuit away from the display area;

The start signal line ESTV, the second clock signal line CB, the first clock signal line CK, the reset line VEL, and the second low voltage line VGL2 are arranged in a direction close to the display area.

The first low voltage line VGL is arranged on the side of the driving circuit close to the display area;

As shown in FIG. 25, the first high voltage line VGH is connected to the first electrode So of To, and the second high voltage line VGH2 is arranged on the side of the first high voltage line VGH away from To;

The first low voltage line VGL is connected to the second electrode Df of Tf.

In at least one embodiment corresponding to FIG. 21, the driving circuit includes a first circuit part and a second circuit part; the first circuit part includes a first transistor T1, a second transistor T2, a third transistor T3, a fourth transistor T4, a fifth transistor T5, a sixth transistor T6, a seventh transistor T7, an eighth transistor T8, a ninth transistor T9, a tenth transistor T10 and an eleventh transistor T11, the second circuit part includes an output transistor To and an output reset transistor Tf;

The first circuit part is arranged between the second low voltage line VGL2 and the second high voltage line VGH2, and the second circuit part is arranged between the second high voltage line VGH2 and the first low voltage line VGL.

As shown in FIGS. 21-25, T2 and T6 are adjacent to VGL2, which facilitates the electrical connection between the gate electrode G2 of T2 and the gate electrode G6 of T6, and VGL;

T1 is adjacent to VGL2 so that the first electrode of T1 is electrically connected to VGL2.

In FIG. 23, the one labeled G1 is the gate electrode of T1, the one labeled G2 is the gate electrode of T2, the one labeled G3 is the gate electrode of T3, the one labeled G4 is the gate electrode of T4, and the one labeled G5 is the gate electrode of T5, the one labeled G6 is the gate electrode of T6, the one labeled G7 is the gate electrode of T7, the one labeled G8 is the gate electrode of T8, the one labeled G9 is the gate electrode of T9, and the one labeled G10 is the gate electrode of T10, the one labeled G11 is the gate electrode of T11, the one labeled Go is the gate electrode of To, and the one labeled Gf is the gate electrode of Tf;

In FIG. 23, the one labeled C2a is the first electrode plate of C2, and in FIG. 24, the one labeled C2b is the second electrode plate of C2;

In FIG. 23, the one labeled C3a is the first electrode plate of C3, and in FIG. 24, the one labeled C3b is the second electrode plate of C3;

In FIG. 23, the one labeled C1a is the first electrode plate of C1, and in FIG. 24, the one labeled C1b is the second electrode plate of C2.

As shown in FIGS. 21-25, the gate electrode G4 of T4 is electrically connected to VEL, the first electrode of T4 is electrically connected to VGH2 through a via hole, and the first electrode of T5 is electrically connected to VGH2 through a via hole.

In FIG. 22, the one labeled Al is the active layer pattern of T1, the one labeled A2 is the active layer pattern of T2, the one labeled A3 is the active layer pattern of T3, the one labeled A4 is the active layer pattern of T4, the one labeled A5 is the active layer pattern of T5, the one labeled A6 is the active layer pattern of T6, the one labeled A7 is the active layer pattern of T7, and the one labeled A8 is the active layer pattern of T8, the one labeled A9 is the active layer pattern of T9, the one labeled A10 is the active layer pattern of T10, the one labeled A11 is the active layer pattern of T11, and the one labeled A0 is the first active layer pattern;

The first active layer pattern A0 includes an active layer pattern of To and an active layer pattern of Tf.

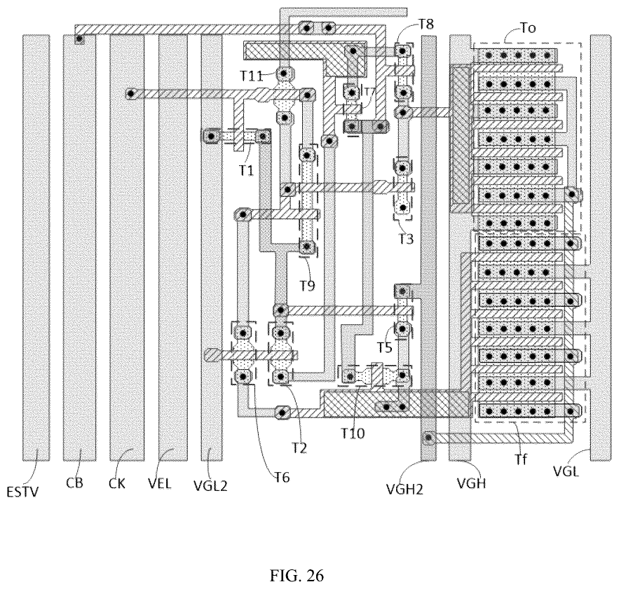

FIG. 26 is a layout diagram of the driving circuit shown in FIG. 19 of at least one embodiment of the present disclosure.

The difference between the layout shown in FIG. 26 and at least one embodiment of the driving circuit shown in FIG. 21 is that T4 is not provided.

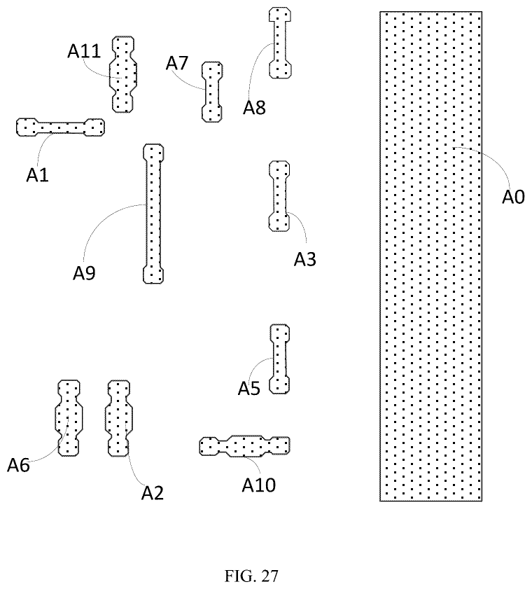

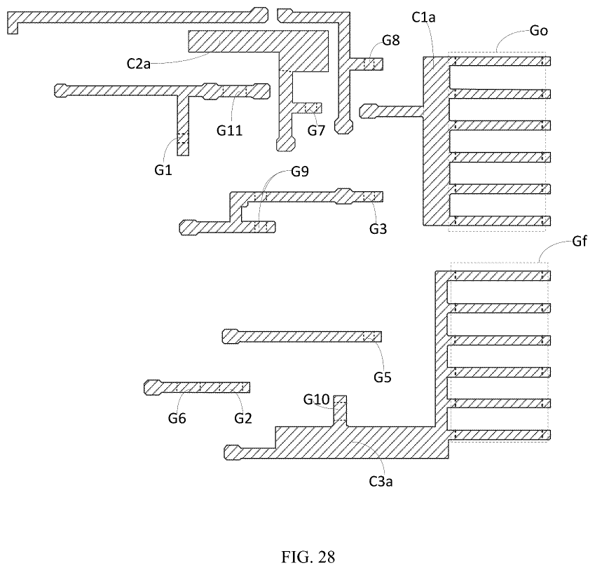

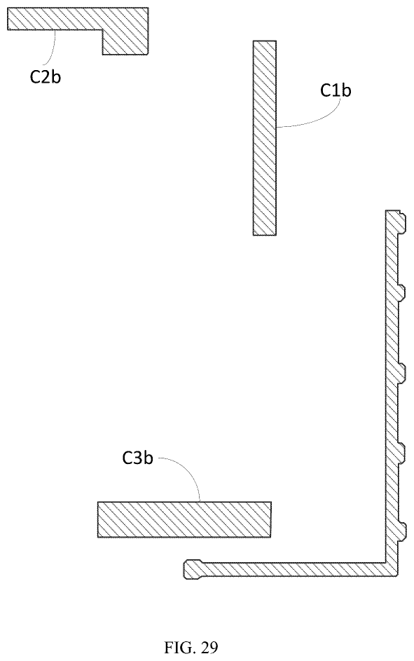

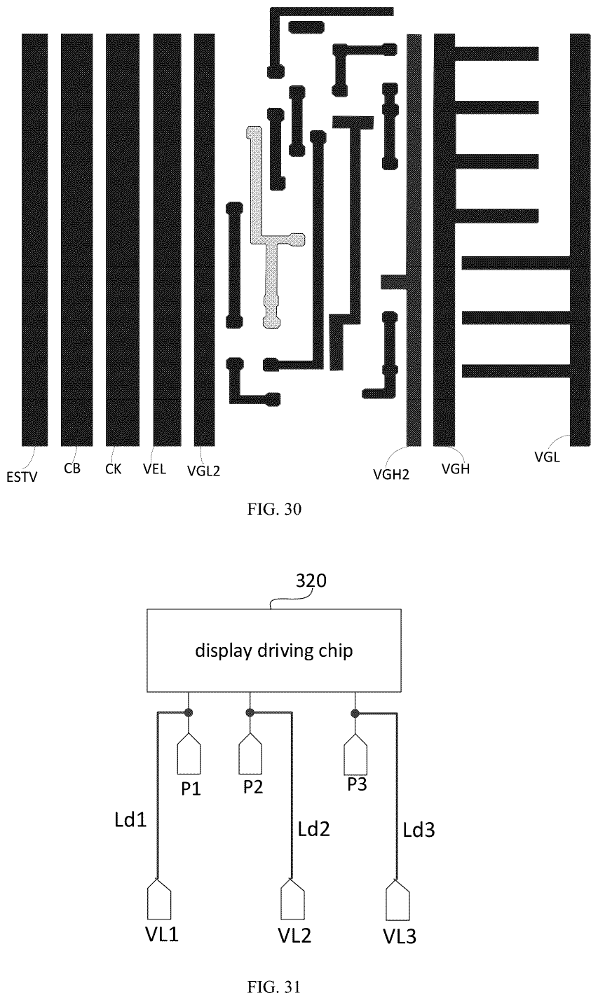

FIG. 27 is a layout diagram of the active layer in FIG. 26, FIG. 28 is a layout diagram of the first gate metal layer in FIG. 26, FIG. 29 is a layout diagram of the second gate metal layer in FIG. 26, FIG. 30 is a layout diagram of the source-drain metal layer in FIG. 26.

The display panel described in the embodiment of the present disclosure includes the driving circuit; the display panel further includes a display driving chip;

The first low voltage input terminal is electrically connected to the first low voltage line, the second low voltage input terminal is electrically connected to the second low voltage line, the third low voltage input terminal is electrically connected to the third low voltage line, and the first low voltage line, the second low voltage line, and the third low voltage line are electrically connected to different pins of the display driving chip, and the display driving chip is configured to provide the first low voltage signal for the first low voltage line, provide the second low voltage signal for the second low voltage line, and provide the third low voltage signal for the third low voltage line; or,

The first low voltage input terminal is electrically connected to the first low voltage line, the second low voltage input terminal and the third low voltage input terminal are both electrically connected to the second low voltage line, and the first low voltage line and the second low voltage line are respectively electrically connected to different pins of the display driving chip, the display driving chip is configured to provide the first low voltage signal for the first low voltage line, and provide the second low voltage signal for the second low voltage line; or,

Both the first low voltage input terminal and the second low voltage input terminal are electrically connected to the first low voltage line, the third low voltage input terminal is electrically connected to the second low voltage line, and the first low voltage line and the second low voltage line are respectively electrically connected to different pins of the display driving chip, the display driving chip is configured to provide the first low voltage signal for the first low voltage line, and provide the second low voltage signal for the second low voltage line; or,

Both the first low voltage input terminal and the third low voltage input terminal are electrically connected to the first low voltage line, the second low voltage input terminal is electrically connected to the second low voltage line, and the first low voltage line and the second low voltage line are respectively electrically connected to different pins of the display driving chip, and the display driving chip is configured to provide the first low voltage signal for the first low voltage line, and provide the second low voltage signal for the second low voltage line.

As shown in FIG. 31, the display panel includes a display driving chip 320;

The first low voltage input terminal VL1 is electrically connected to the first low voltage line Ld1, the second low voltage input terminal VL2 is electrically connected to the second low voltage line Ld2, and the third low voltage input terminal VL3 is electrically connected to the third low voltage line Ld3, the first low voltage line Ld1 is electrically connected to the first pin P1 of the display driving chip 320, the second low voltage line Ld2 is electrically connected to the second pin P2 of the display driving chip 320, and the third low voltage line Ld3 is electrically connected to the third pin P3 of the display driving chip 320;

The display driving chip 320 is configured to provide the first low voltage signal for the first low voltage line Ld1, provide the second low voltage signal for the second low voltage line Ld2, and provide the third low voltage signal for the third low voltage line Ld3.

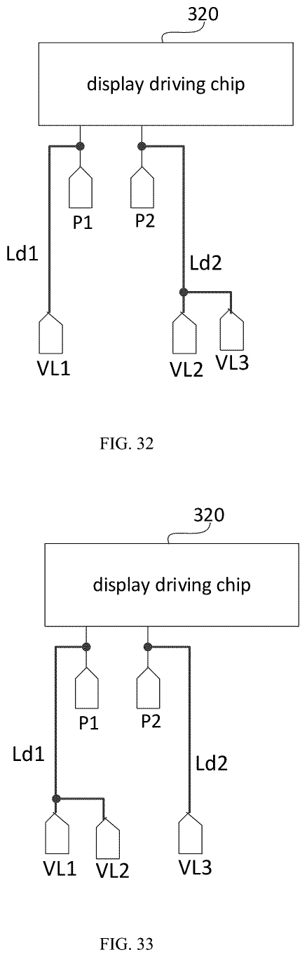

As shown in FIG. 32, the display panel includes a display driving chip 320;

The first low voltage input terminal VL1 is electrically connected to the first low voltage line Ld1, and the second low voltage input terminal VL2 and the third low voltage input terminal VL3 are both electrically connected to the second low voltage line Ld2;

The first low voltage line Ld1 is electrically connected to the first pin P1 of the display driving chip 320, and the second low voltage line Ld2 is electrically connected to the second pin P2 of the display driving chip 320;

The display driving chip 320 is configured to provide a first low voltage signal for the first low voltage line Ld1 and provide a second low voltage signal for the second low voltage line Ld2.

As shown in FIG. 33, the display panel includes a display driving chip 320;

Both the first low voltage input terminal VL1 and the second low voltage input terminal VL2 are electrically connected to the first low voltage line Ld1, and the third low voltage input terminal VL3 is electrically connected to the second low voltage line Ld2;

The first low voltage line Ld1 is electrically connected to the first pin P1 of the display driving chip 320, and the second low voltage line Ld2 is electrically connected to the second pin P2 of the display driving chip 320;

The display driving chip 320 is configured to provide a first low voltage signal for the first low voltage line Ld1 and provide a second low voltage signal for the second low voltage line Ld2.

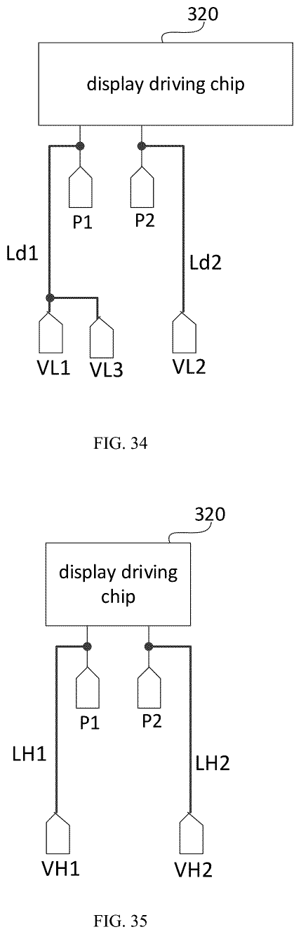

As shown in FIG. 34, the display panel includes a display driving chip 320;

Both the first low voltage input terminal VL1 and the third low voltage input terminal VL3 are electrically connected to the first low voltage line Ld1, and the second low voltage input terminal VL2 is electrically connected to the second low voltage line Ld2;

The first low voltage line Ld1 is electrically connected to the first pin P1 of the display driving chip 320, and the second low voltage line Ld2 is electrically connected to the second pin P2 of the display driving chip 320;

The display driving chip 320 is configured to provide a first low voltage signal for the first low voltage line Ld1 and provide a second low voltage signal for the second low voltage line Ld2.

The display panel described in the embodiment of the present disclosure includes the driving circuit; the display panel further includes a display driving chip;

The first high voltage input terminal is electrically connected to the first high voltage line, and the second high voltage input terminal is electrically connected to the second high voltage line; the first high voltage line and the second high voltage line are respectively electrically connected to different pins of the display driving chip, the display driving chip is configured to provide the first high voltage signal for the first high voltage line, and the display driving chip is configured to provide the second high voltage signal for the second high voltage line.

As shown in FIG. 35, the display panel includes a display driving chip 320;

Both the first low voltage input terminal VL1 and the third low voltage input terminal VL3 are electrically connected to the first low voltage line Ld1, and the second low voltage input terminal VL2 is electrically connected to the second low voltage line Ld2;

The first low voltage line Ld1 is electrically connected to the first pin P1 of the display driving chip 320, and the second low voltage line Ld2 is electrically connected to the second pin P2 of the display driving chip 320;

The display driving chip 320 is configured to provide a first low voltage signal for the first low voltage line Ld1 and provide a second low voltage signal for the second low voltage line Ld2.

The display device described in the embodiment of the present disclosure includes the driving circuit.

The display device provided by the embodiments of the present disclosure may be any product or component with a display function, such as a mobile phone, a tablet computer, a television, a monitor, a notebook computer, a digital photo frame, a navigator, and the like.

The above descriptions are implementations of the present disclosure. It should be pointed out that those skilled in the art can make some improvements and modifications without departing from the principle of the present disclosure. These improvements and modifications shall also fall within the scope of the present disclosure.

1. A driving circuit, comprising a first node control circuit, a second node control circuit and a first output circuit; wherein
the second node control circuit is electrically connected to a first low voltage input terminal, a first node and a second node respectively, and is configured to control to connect the first node and the second node under the control of a low voltage signal provided by the first low voltage input terminal;
the first node control circuit is electrically connected to a second low voltage input terminal, a first clock signal line and the first node respectively, and is configured to control to connect the first node and the second low voltage input terminal under the control of a first clock signal provided by the first clock signal line;
the first output circuit is electrically connected to a pull-down node, a driving signal output terminal and a third low voltage input terminal respectively, and is configured to control to connect the driving signal output terminal and the third low voltage input terminal under the control of a potential of the pull-down node;
at least two of the first low voltage input terminal, the second low voltage input terminal and the third low voltage input terminal are different from each other.

2. The driving circuit according to claim 1, further comprising a second output circuit and a fourth node control circuit; wherein
the second output circuit is respectively electrically connected to a pull-up node, a first high voltage input terminal and the driving signal output terminal, and is configured to control to connect the first high voltage input terminal and the driving signal output terminal under the control of a potential of the pull-up node;
the fourth node control circuit is electrically connected to the first node, a fourth node and a fourth high voltage input terminal, and is configured to control to connect the fourth node and the fourth high voltage input terminal under the control of a potential of the first node;
the first high voltage input terminal is different from the fourth high voltage input terminal.

3. The driving circuit according to claim 2, further comprising a third node reset circuit; wherein
the third node reset circuit is respectively electrically connected to a reset line, a third high voltage input terminal and a third node, and is configured to control to connect the third high voltage input terminal and the third node under the control of a reset signal provided by the reset line;
the third high voltage input terminal is different from at least one of the first high voltage input terminal or the fourth high voltage input terminal.

4. The driving circuit according to claim 2, further comprising a pull-up node control circuit; wherein
the pull-up node control circuit is electrically connected to the third node, a second high voltage input terminal and the pull-up node, and is configured to control to connect the second high voltage input terminal and the pull-up node under the control of a potential of the third node;
the second high voltage input terminal is different from at least one of the first high voltage input terminal or the fourth high voltage input terminal.

5. The driving circuit according to claim 3, further comprising a pull-up node control circuit; wherein
the pull-up node control circuit is electrically connected to the third node, the second high voltage input terminal and the pull-up node, and is configured to control to connect the second high voltage input terminal and the pull-up node under the control of the potential of the third node;
the second high voltage input terminal is different from the third high voltage input terminal.

6. The driving circuit according to claim 1, further comprising a pull-down node control circuit; wherein
the pull-down node control circuit is electrically connected to a fourth low voltage input terminal, a third node, and the pull-down node, and is configured to control to connect the third node and the pull-down node under the control of a low voltage signal provided by the fourth low voltage input terminal;
the fourth low voltage input terminal is different from at least one of the first low voltage input terminal, the second low voltage input terminal, or the third low voltage input terminal,
wherein the pull-down node control circuit comprises a sixth transistor; a control electrode of the sixth transistor is electrically connected to the fourth low voltage input terminal, a first electrode of the sixth transistor is electrically connected to the third node, and a second electrode of the sixth transistor is electrically connected to the pull-down node.

7. The driving circuit according to claim 2, further comprising a fifth node control circuit and a pull-up node control circuit; wherein
the fifth node control circuit is electrically connected to the second node, a fifth node, and a second clock signal line, and is configured to connect the second clock signal line and the fifth node under the control of the potential of the second node, and control a potential of the fifth node according to the potential of the second node;
the pull-up node control circuit is also electrically connected to the fifth node, the second clock signal line and the pull-up node, and is configured to control to connect the fifth node and the pull-up node under the control of a second clock signal provided by the second clock signal line and maintain the potential of the pull-up node under the control of the second clock signal provided by the second clock signal line.

8. The driving circuit according to claim 4, further comprising a third node control circuit; wherein
the third node control circuit is electrically connected to a start voltage terminal, the first clock signal line and the third node, and is configured to control to connect the start voltage terminal and the third node under the control of the first clock signal provided by the first clock signal line;
the first node control circuit is also electrically connected to the third node, the first node, and the first clock signal line, and is configured to control to connect the first node and the first clock signal line under the control of the potential of the third node;
the fourth node control circuit is also electrically connected to the pull-down node and the second clock signal line, and is configured to control to connect the fourth node and the second clock signal line under the control of the potential of the pull-down node and control the potential of the fourth node according to the potential of the pull-down node.

9. The driving circuit according to claim 1, wherein the first node control circuit comprises a first transistor, and the second node control circuit comprises a second transistor;
a control electrode of the first transistor is electrically connected to the first clock signal line, a first electrode of the first transistor is electrically connected to the second low voltage input terminal, and a second electrode of the first transistor is electrically connected to the first node;
a control electrode of the second transistor is electrically connected to the first low voltage input terminal, a first electrode of the second transistor is electrically connected to the first node, and a second electrode of the second transistor is electrically connected to the second node;
the first output circuit includes an output reset transistor; a control electrode of the output reset transistor is electrically connected to the pull-down node, a first electrode of the output reset transistor is electrically connected to the driving signal output terminal, and a second electrode of the output reset transistor is electrically connected to the third low voltage input terminal.

10. The driving circuit according to claim 4, wherein the second output circuit comprises an output transistor, and the pull-up node control circuit comprises a third transistor and a first capacitor;
a control electrode of the output transistor is electrically connected to the pull-up node, a first electrode of the output transistor is electrically connected to the first high voltage input terminal, and a second electrode of the output transistor is electrically connected to the driving signal output terminal;
a control electrode of the third transistor is electrically connected to the third node, a first electrode of the third transistor is electrically connected to the second high voltage input terminal, and a second electrode of the third transistor is electrically connected to the pull-up node;
a first electrode plate of the first capacitor is electrically connected to the pull-up node, and a second electrode plate of the first capacitor is electrically connected to the first high voltage input terminal.

11. The driving circuit according to claim 3, wherein the third node reset circuit comprises a fourth transistor;
a control electrode of the fourth transistor is electrically connected to the reset line, a first electrode of the fourth transistor is electrically connected to the third high voltage input terminal, and a second electrode of the fourth transistor is electrically connected to the third node.

12. The driving circuit according to claim 2, wherein the fourth node control circuit comprises a fifth transistor;
a control electrode of the fifth transistor is electrically connected to the first node, a first electrode of the fifth transistor is electrically connected to the fourth high voltage input terminal, and a second electrode of the fifth transistor is electrically connected to the fourth node.

13. (canceled)

14. The driving circuit according to claim 7, wherein the fifth node control circuit comprises a seventh transistor and a second capacitor; the pull-up node control circuit further comprises an eighth transistor;
a control electrode of the seventh transistor is electrically connected to the second node, a first electrode of the seventh transistor is electrically connected to the second clock signal line, and a second electrode of the seventh transistor is electrically connected to a fifth node;
a first electrode plate of the second capacitor is electrically connected to the second node, and a second electrode plate of the second capacitor is electrically connected to the fifth node;
a control electrode of the eighth transistor is electrically connected to the second clock signal line, a first electrode of the eighth transistor is electrically connected to the fifth node, and a second electrode of the eighth transistor is electrically connected to the pull-up node.

15. The driving circuit according to claim 8, wherein the first node control circuit further comprises a ninth transistor;
a control electrode of the ninth transistor is electrically connected to the third node, a first electrode of the ninth transistor is electrically connected to the first clock signal line, and a second electrode of the ninth transistor is electrically connected to the first node;
the fourth node control circuit further includes a tenth transistor and a third capacitor;
a control electrode of the tenth transistor is electrically connected to the pull-down node, a first electrode of the tenth transistor is electrically connected to the second clock signal line, and a second electrode of the tenth transistor is electrically connected to the fourth node;
a first electrode plate of the third capacitor is electrically connected to the pull-down node, and a second electrode plate of the third capacitor is electrically connected to the fourth node;
the third node control circuit includes an eleventh transistor;
a control electrode of the eleventh transistor is electrically connected to the first clock signal line, a first electrode of the eleventh transistor is electrically connected to the start voltage terminal, and a second electrode of the eleventh transistor is electrically connected to the third node.

16. A driving circuit, comprising a first transistor, a second transistor, an output reset transistor and a sixth transistor; wherein
a control electrode of the first transistor is electrically connected to a first clock signal line, a first electrode of the first transistor is electrically connected to a second low voltage input terminal, and a second electrode of the first transistor is electrically connected to a first node;
a control electrode of the second transistor is electrically connected to a first low voltage input terminal, a first electrode of the second transistor is electrically connected to the first node, and a second electrode of the second transistor is electrically connected to a second node;
the first output circuit includes the output reset transistor, a control electrode of the output reset transistor is electrically connected to a pull-down node, a first electrode of the output reset transistor is electrically connected to a driving signal output terminal, and a second electrode of the output reset transistor is electrically connected to a third low voltage input terminal;
a control electrode of the sixth transistor is electrically connected to a fourth low voltage input terminal, a first electrode of the sixth transistor is electrically connected to a third node, and a second electrode of the sixth transistor is electrically connected to the pull-down node;
the first low voltage input terminal, the second low voltage input terminal, the third low voltage input terminal and the fourth low voltage input terminal are not completely the same.

17. A driving circuit, comprising an output transistor, a third transistor, a fourth transistor and a fifth transistor; wherein
a control electrode of the output transistor is electrically connected to a pull-up node, a first electrode of the output transistor is electrically connected to a first high voltage input terminal, and a second electrode of the output transistor is electrically connected to a driving signal output terminal;
a control electrode of the third transistor is electrically connected to a third node, a first electrode of the third transistor is electrically connected to a second high voltage input terminal, and a second electrode of the third transistor is electrically connected to the pull-up node;
a control electrode of the fourth transistor is electrically connected to a reset line, a first electrode of the fourth transistor is electrically connected to a third high voltage input terminal, and a second electrode of the fourth transistor is electrically connected to a third node;
a control electrode of the fifth transistor is electrically connected to a first node, a first electrode of the fifth transistor is electrically connected to a fourth high voltage input terminal, and a second electrode of the fifth transistor is electrically connected to a fourth node;
the first high voltage input terminal, the second high voltage input terminal, the third high voltage input terminal and the fourth high voltage input terminal are not completely the same.

18. A display panel, comprising the driving circuit according to claim 1; wherein the display panel further comprises a display driving chip;
the first low voltage input terminal is electrically connected to a first low voltage line, the second low voltage input terminal is electrically connected to a second low voltage line, the third low voltage input terminal is electrically connected to a third low voltage line, and the first low voltage line, the second low voltage line, and the third low voltage line are electrically connected to different pins of the display driving chip, and the display driving chip is configured to provide a first low voltage signal for the first low voltage line, provide a second low voltage signal for the second low voltage line, and provide a third low voltage signal for the third low voltage line; or,
the first low voltage input terminal is electrically connected to the first low voltage line, the second low voltage input terminal and the third low voltage input terminal are both electrically connected to the second low voltage line, and the first low voltage line and the second low voltage line are respectively electrically connected to different pins of the display driving chip, the display driving chip is configured to provide the first low voltage signal for the first low voltage line, and provide the second low voltage signal for the second low voltage line; or,
both the first low voltage input terminal and the second low voltage input terminal are electrically connected to the first low voltage line, the third low voltage input terminal is electrically connected to the second low voltage line, and the first low voltage line and the second low voltage line are respectively electrically connected to different pins of the display driving chip, the display driving chip is configured to provide the first low voltage signal for the first low voltage line, and provide the second low voltage signal for the second low voltage line; or,
both the first low voltage input terminal and the third low voltage input terminal are electrically connected to the first low voltage line, the second low voltage input terminal is electrically connected to the second low voltage line, and the first low voltage line and the second low voltage line are respectively electrically connected to different pins of the display driving chip, and the display driving chip is configured to provide the first low voltage signal for the first low voltage line, and provide the second low voltage signal for the second low voltage line.

19. A display panel, comprising the driving circuit according to claim 4; wherein the display panel further comprises a display driving chip;
the first high voltage input terminal is electrically connected to a first high voltage line, and the second high voltage input terminal is electrically connected to a second high voltage line; the first high voltage line and the second high voltage line are respectively electrically connected to different pins of the display driving chip, the display driving chip is configured to provide a first high voltage signal for the first high voltage line, and the display driving chip is configured to provide a second high voltage signal for the second high voltage line.

20. A display substrate, comprising a base substrate and the driving circuit according to claim 1 arranged on the base substrate,
wherein the driving circuit comprises a first low voltage line, a second low voltage line, a first high voltage line, a second high voltage line, a first node control circuit, a second node control circuit, a first output circuit, a second output circuit, a pull-up node control circuit, a fourth node control circuit, a pull-down node control circuit, a fifth node control circuit and a third node control circuit;
the second low voltage line is arranged on a side of the driving circuit away from a display area, and the first low voltage line is arranged on a side of the driving circuit close to the display area;
the first high voltage line and the second high voltage line are arranged between a first circuit part included in the driving circuit and a second circuit part included in the driving circuit;
the first circuit part includes the first node control circuit, the second node control circuit, the pull-up node control circuit, the fourth node control circuit, the pull-down node control circuit, the fifth node control circuit and the third node control circuit, the second circuit part includes the first output circuit and the second output circuit;
the first circuit part is arranged between the second low voltage line and the second high voltage line, and the second circuit part is arranged between the first high voltage line and the first low voltage line,
wherein the driving circuit further includes a third node reset circuit, and the first circuit part includes the third node reset circuit.

21.-22. (canceled)

23. A display device comprising the driving circuit according to claim 1.
